(19) United States
(12) Patent Application Publication
(10) Pub. No.: US 2010/0025852 A1
(43) Pub. Date: Feb. 4, 2010

(54) SEMICONDUCTOR DEVICE AND METHOD FOR MANUFACTURING THE SAME

(76) Inventors: Makoto Ueki, Tokyo (JP); Hironori Yamamoto, Tokyo (JP); Yoshihiro Hayashi, Tokyo (JP); Fuminori Ito, Tokyo (JP); Yoshiyuki Fukumoto, Tokyo (JP)

Correspondence Address: Mr. Jackson Chen, 6535 N. STATE HWY 161, IRVING, TX, 75039, US

(21) Appl. No.: 12/518,688

(22) PCT Filed: Dec. 20, 2007
(86) PCT No.: PCT/JP2007/074543

§ 371 Date: Jun. 11, 2009

(51) Int. Cl. H01L 23/48; H01L 21/312; H01L 21/768

(52) U.S. Cl. 257/761; 257/741; 257/762; 438/780; 438/675; 438/653; 438/761; 438/678; 257/E23.01; 257/E21.26; 257/E21.586; 257/E21.584

(57) ABSTRACT

To suppress deterioration in reliability of wiring and to reduce effective dielectric constant of wiring. In a semiconductor device, copper-containing wirings are covered by barrier insulating films, and the barrier insulating films contain a component of an organic silica containing unsaturated hydrocarbon and amorphous carbon. The copper-containing wirings are covered by the barrier insulating films that contain a component that is in an organic silica structure containing unsaturated hydrocarbon and amorphous carbon. Accordingly, inter-wiring capacitance is reduced without deteriorating reliability of the copper-containing wiring, thereby realizing a high-speed LSI with low power consumption.

### TECHNICAL FIELD

The present invention relates to a semiconductor device and, more specifically, to a highly reliable copper wiring structure and a manufacturing method thereof.

### BACKGROUND ART

In general, aluminum (Al) or Al alloy has widely been used as a wiring material of a semiconductor device, and silica (SiO₂) has widely been used as an interlayer insulating film material of a semiconductor device. However, in accordance with advancements in micronization and high-speed in the semiconductor device, copper (Cu) exhibiting a still lower resistance has become popular to be used as a wiring material and a low-permittivity film having a still lower permittivity has become popular to be used for an insulating film in order to improve signal transmission delay generated in the wiring. Normally, a damascene method is used when forming a Cu wiring, since it is difficult to process Cu by dry etching. With the damascene method, a groove is formed in an insulating film formed on a semiconductor substrate, Cu is embedded in the groove, and excessive Cu other than Cu in the wiring groove is polished to form a Cu wiring. Further, when Cu is used as a wiring material, it is necessary to provide a barrier layer in the periphery of Cu in order to prevent Cu from diffusing into the insulating film and to prevent corrosion of Cu. Hereinafter, a currently-used typical Cu wiring manufacturing method will be described by referring to drawings.

FIG. 37A shows a lower-layer wiring on which an upper-layer wiring is formed. This part can also be formed by using a same process as that of the upper layer described below. An insulating film 1b is formed thereon (FIG. 37b), and wiring grooves and wiring holes are formed in the insulating film thereafter by lithography and anisotropic etching (FIG. 37C). Subsequently, a barrier film 2b that is a semiconductor film is formed, and Cu 3b is embedded (FIG. 37D). Then, excessive Cu and semiconductor barrier film other than those in the wiring grooves or the wiring holes are removed by chemical mechanical polishing (CMP) (FIG. 37E), and a barrier film 4b as an insulator is formed to create a Cu wiring structure in which the bottom face and the side face are covered by a barrier metal layer that is a conductor and the top face is covered by the barrier layer that is the insulating film (FIG. 37F).

As the barrier insulating film for covering the Cu wiring surface, silicon nitride (SiN), silicon carbon nitride (SiCN), or the like used. In general, however, relative dielectric constants of those are as high as 5.0 or more, which results in reducing the effective dielectric constant of the wiring. This makes it difficult to improve signal transmission delays generated on the wirings. For reducing the effective dielectric constant of the wiring, there have been studies conducted to apply a film with a still lower relative dielectric constant as the barrier insulating film. Patent Document 1 discloses a technique regarding a SiCN film whose dielectric constant is reduced to about 4.0 while maintaining a Cu diffusion resistant property through controlling a raw material gas and a film-forming condition. Further, as a method for reducing the dielectric constant of the barrier film, Patent Document 2 discloses a technique which forms an insulating film having a Cu barrier characteristic and the relative dielectric constant in a range of 3.4-4.3 through executing plasma reaction by using an oxygen-containing gas and an alkoxy compound having Si—H linkage or siloxane having Si—H linkage as a film-forming gas.

In that case, a Cu diffusion preventing effect is insufficient or adhesive property with Cu is insufficient. Therefore, there is such an issue in terms of reliability that electromigration (EM) resistant property is deteriorated so that the wiring becomes easily cut. Further, when a low-dielectric-constant film is formed on Cu with a film-forming gas containing oxygen (O), there is such an issue that the reliability becomes extremely deteriorated since the surface of Cu is oxidized when forming the film.
Patent Document 1: Japanese Unexamined Patent Publication 2004-289105
Patent Document 2: Japanese Unexamined Patent Publication 2002-164429

However, when the technique depicted in Patent Document 1 is used, the relative dielectric constant can only be reduced to about 4.0. Thus, for reducing the relative dielectric constant further, issues such as reduction in the film density, deterioration in the Cu diffusion resistant property, deterioration in the adhesive property with Cu, and the like are raised. Further, there is also such an issue generated in terms of reliability that electromigration (EM) resistant property is deteriorated so that the wiring becomes easily cut. Meanwhile, when the technique depicted in Patent Document 2 is used, the surface of Cu is oxidized while forming the film when the film is formed directly on Cu, since the film-forming gas contains oxygen. This results in having a cut in the wiring easily due to deterioration in EM resistant property and stress migration (SM).

An object of the present invention is to provide a semiconductor device in which deterioration in the reliability of the wirings can be suppressed and the effective dielectric constant of the wirings is reduced, and to provide a manufacturing method thereof.

### DISCLOSURE OF THE INVENTION

In order to achieve the foregoing object, the semiconductor device according to the present invention is a semiconductor device having a copper-containing wiring, wherein: the copper-containing wiring is covered by a barrier insulating film; and the barrier insulating film contains a component of organic silica which contains unsaturated hydrocarbon and amorphous carbon.

The semiconductor device manufacturing method according to the present invention is a method for manufacturing a semiconductor device having a copper-containing wiring. The method covers the copper-containing wiring by a barrier insulating film of an organic silica structure which contains unsaturated hydrocarbon and amorphous carbon.

With the present invention, it is possible to reduce the inter-wiring capacitance without deteriorating the reliability of the copper-containing wirings. Therefore, it is possible to achieve high-speed and low power consuming LSI.

### BEST MODES FOR CARRYING OUT THE INVENTION

Hereinafter, embodiments of the present invention will be described in detail by referring to the drawings.

As shown in FIG. 1, FIG. 10, FIG. 11, FIG. 14, FIG. 15, and FIG. 18, a semiconductor device according to the embodiments of the present invention has a copper-containing wiring as a basic structure. In the semiconductor device, the copper-containing wirings (3a, 3b, 16, 23, 30, 43a, 43b) are covered by barrier insulating films (4a, 4b, 5a, 5b, 17, 18, 24, 25, 45, 46), and the barrier insulating films contain a component that is in an organic silica structure containing unsaturated hydrocarbon and amorphous carbon.

For manufacturing the semiconductor device according to the embodiments of the present invention, the copper-containing wirings are covered by the barrier insulating films that contain a component that is in an organic silica structure containing unsaturated hydrocarbon and amorphous carbon.

In the embodiments of the present invention, organic silica containing the unsaturated hydrocarbon and amorphous carbon is selected as a compound for forming the barrier insulating films. It has been verified that the organic silica has Cu diffusion resistant property and its relative dielectric constant is less than 3.5. The copper-containing wirings are covered by the barrier insulating film of the organic silica structure.

In the embodiments of the present invention, the copper-containing wirings are Covered by the barrier insulating films. Thus, it is possible to improve the reliability of the copper-containing wirings without deteriorating the characteristic of the copper-containing wirings.

The barrier insulating film may be formed in a single-layer structure or a double-layer structure to cover the copper-containing wiring.

Next, the semiconductor device according to the present invention will be described in more details based on a concretive example.

First, the insulating film in this Description is a film (inter-layer insulating film) which insulates/separates wiring materials, for example. For the low-dielectric-constant insulating film, a material whose relative dielectric constant is lower than that of a silicon oxide film (relative dielectric constant: 4.5) is used in order to reduce the capacitance between multilayer wirings which connect semiconductor elements. Particularly, as examples of a perforated insulating film, there are a material whose relative dielectric constant is reduced by making a silicon oxide film to have porosity, an HSQ (hydrogen silsequioxane) film, a material whose relative dielectric constant is reduced by making SiOCH, SiOC (Black Diamond™, CORAL™, Aurora™, for example) or the like be porous, etc. It is desired to reduce the dielectric constant of such films further.

Further, a metal wiring material means a material having Cu as a main component. That is, it means a raw material of the copper-containing wiring. In order to improve the reliability of the metal wiring material, a metal element other than Cu may be contained in a member configured with Cu, or a metal element other than Cu may be formed on the top face, the side face, or the like of Cu.

Further, a damascene wiring means an embedded wiring which is formed by embedding a metal wiring material in a groove of an inter-layer insulating film formed in advance, and removing the excessive metal other than the metal inside the groove by CMP, for example. When forming the damascene wiring by Cu, typically employed is a wiring structure in which the side face and the outer periphery of the Cu wiring are covered by a barrier metal, and the top face of the Cu wiring is covered by an insulating barrier film.

Further, the CMP (Chemical Mechanical Polishing) method is used for flattening the unevenness on the surface of a wafer generated during a multilayer wiring forming process, through polishing the unevenness by having the surface in contact with a rotating polishing pad while applying a polisher onto the wafer surface. When forming the wiring by the damascene method, it is particularly used to obtain a flat wiring surface by removing the excessive metal part after embedding a metal to the wiring groove or a via hole.

Further, for the barrier metal, a conductive film having a barrier characteristic for covering the side face and the bottom face of the wiring is used for preventing the metal element configuring the wiring from being diffused into the interlayer insulating film and the lower layer. For example, when the wiring is made with a metal element having Cu as a main component, metals with high melting points such as tantalum (Ta), tantalum nitride (TaN), titanium nitride (TiN), and tungsten carbon nitride (WCN), nitrides or the like of those, or a laminated film of those are used.

Further, the semiconductor substrate is a substrate on which the semiconductor device is formed, and it includes not only such type formed on a single crystalline silicon substrate but also substrates such as an SOI (Silicon on Insulator) substrate, a TFT (Thin film transistor), and a liquid crystal manufacturing substrate.

Furthermore, a hard mask is used for protection by being laminated over an interlayer insulating film, when it is difficult to perform direct CMP due to a decrease in the strength because of the low dielectric constant of the interlayer insulating film.

Moreover, a passivation film is formed on the uppermost layer of the semiconductor element, and it is used for protecting the semiconductor element from water or the like from the outside. In the embodiments of the present invention, a silicon oxide nitride film (SiON), a polyimide film, or the like formed by a plasma CVD method is used.

Further, the plasma CVD method is used for forming a continuous film on a substrate by continuously supplying gaseous raw material into a reaction chamber under decompression, for example, to excite modules with a plasma energy and executing a gas phase reaction, a substrate surface reaction, or the like.

As a PVD method, a normal sputtering method may be used. However, in order to improve the embedding characteristic, to improve the film quality, and to obtain uniformity in the thickness within the surface of the wafer, a highly-directional sputtering method such as a long/slow sputtering method, a collimate sputtering method, an ionized sputtering method, or the like is used. When sputtering an alloy, a formed metal film can be formed into an alloy film through having a metal other than a main component contained within a target metal by an amount less than the solubility limit. In the embodiments of the present invention, the PVD method is mainly used when forming a Cu seed layer and a barrier metal layer at the time of forming a damascene Cu wiring.

Further, a surface reforming method or a film-forming method using gas cluster ions is used when forming a modified layer and a film through: forming an aggregate of several hundreds to several thousands of atoms and molecules by adiabatic expansion occurred at the time of ejecting a raw material gas into a vacuum from a nozzle; ionizing it by applying electrons; and accelerating it to have a desired energy to be irradiated to a target. In this method, the energy per atom is small. Thus, in addition to enabling creation of a thin reform layer and reduction in defects on the surface, the method can be characterized that it does not require the film-thickness controllability for the ultra thin film and heating of the substrate at the time of forming the film.

### First Embodiment

Next, a case of covering the copper-containing wirings with the barrier insulating films formed in a double-layer structure will be described as a first embodiment.

As shown in FIG. 1, in the semiconductor device according to the first embodiment of the present invention, the barrier insulating films are formed in a double-layer structure with inner-layer barrier insulating films 4a, 4b for covering the surface of copper-containing wirings 3a, 3b and outer-layer barrier insulating films 5a, 5b laminated on the inner-layer barrier insulating films 4a, 4b. The copper-containing wirings 3a and 3b are covered by the barrier insulating films 4a, 4b, 5a, and 5b formed in the two-layer structure.

The wiring structure shown in FIG. 1 shows a multilayer wiring structure in which the copper-containing wirings 3a and 3b are formed, respectively, on an lower insulating film 1a and an upper-insulating film 1b, and a part of the copper-containing wiring 3a and a part of the copper-containing wiring 3b are connected. However, the wiring structure is not limited only to the multilayer wiring structure shown in FIG. 1.

In the first embodiment shown in FIG. 1, the inner-layer barrier insulating films 4a, 4b cover the surfaces of the copper-containing wirings 3a, 3b so as to suppress oxidation of the surfaces of the copper-containing wirings 3a, 3b with the inner-layer barrier insulating films 4a, 4b (oxidation preventing layer). The outer-layer barrier insulating films 5a, 5b are laminated on the inner-layer barrier insulating films 4a, 4b. The barrier insulating films shown in FIG. 1 contain components of unsaturated hydrocarbon and amorphous carbon since the outer-layer barrier insulating films 5a, 5b are formed with organic silica that contains unsaturated hydrocarbon and amorphous carbon. Further, it is desirable for the inner-layer insulating films 4a and 4b to be layers that contain no oxygen.

In a process for forming the outer-layer barrier insulating films 5a, 5b having the Cu diffusion resistant characteristic and the relative dielectric constant of less than 3.5, which are in the organic silica structure containing the unsaturated hydrocarbon and amorphous carbon, it is necessary to suppress oxidation of the surfaces of the copper-containing wirings 3a and 3b since O is contained in the film-forming gas. Thus, in the first embodiment, the inner-layer barrier insulating films 4a, 4b as the oxidation preventing layers are formed on the surfaces of the copper-containing wirings 3a, 3b, and the outer-layer barrier insulating films 5a, 5b are formed thereafter. The inner-layer barrier insulating films 4a, 4b are desirable to be formed with SiN, SiCN, or SiC. Further, the film thickness of the inner-layer barrier insulating films 4a and 4b is desirable to be 5 nm or less. This is because the film thickness of the entire barrier insulating films can be suppressed thin through forming the film thickness of the inner-layer barrier insulating films 4a, 4b to be extremely thin, which makes it possible to reduce the effective dielectric constant of the wirings and to improve the delay of the wiring signals. The minimum film thickness of the inner-layer barrier insulating films 4a and 4b change variously depending on the factors such as the conditions in the manufacturing process and the material for the copper-containing wirings, so that it cannot be defined sweepingly. The film thickness may be set arbitrarily, as long as it is the value that can prevent oxidation of the surfaces of the copper-containing wirings.

Next, a method for manufacturing the semiconductor device according to the first embodiment of the present invention will be described by referring to FIG. 2.

First, groves are formed in the insulating film 1a, and the barrier metal film 2a is formed to the inner-walls of the grooves (FIG. 2A). The barrier metal film 2a is for preventing the diffusion of the copper-containing wirings 3a, 3b to be described later, and it may be formed to the inner walls of the grooves as necessary.

Then, a copper-containing metal film is formed by being embedded to the inside the grooves of the insulating film 1a to form the copper-containing wiring film 3a. Then, the inner-layer barrier insulating film 4a is deposited on the insulating film 1a, and the outer-layer insulating film 5a is stacked on the inner-layer barrier insulating film 4a to cover the surface of the copper-containing wiring 3a with the inner-layer insulating film 4a and the outer-layer barrier insulating film 5a (FIG. 2A). The inner-layer barrier insulating film 4a is formed as a barrier insulating film made with SiN, SiCN, or SiC by using the plasma CVD, for example.

Then, the insulating film 1b is deposited on the outer-layer barrier insulating film 5a (FIG. 2A). Thereafter, a wiring groove 1c is formed in the insulating film 1b and a wiring hole 1d reaching to the lower copper-containing wiring 3a is formed on the insulating film 1b through performing lithography and anisotropic etching (FIG. 2C).

Subsequently, a barrier metal film 2b is formed in the wiring groove 1c and the wiring hole 1d of the insulating film 1b, and then a copper-containing metal film is embedded into the wiring groove 1c and the wiring hole 1d of the insulating film 1b to form the copper-containing wiring 3b (FIG. 2D). When forming the copper-containing wirings 3a, 3b with the copper-containing metal film on the insulating films 1a, 1b, a granular type is used for the copper-containing metal film. Thus, heat treatment is applied to the granular type material to form the copper-containing wirings 3a and 3h. The temperature of the heat treatment is set to 200 degrees C.-400 degrees C., and the time thereof is set to 30 seconds-1 hour. Further, the copper-containing wiring 3b formed in the wiring hole 1d of the upper insulating film 1b is electrically connected to a part of the copper-containing wiring 3a of the lower insulating film 1a via the barrier metal film 2b. Thus, the lower copper-containing wiring 3a and the upper copper-containing wiring 3b are in a conductive state.

Subsequently, the extra copper-containing wiring 3b and metal barrier metal film 2b other than those in the wiring groove and the wiring hole are removed by using a polishing technique such as CMP (FIG. 2E).

Then, by using the plasma CVD method, for example, the inner-layer barrier insulating film 4b made with SiN, SiCN, or SiC is deposited on the insulating film 1b (FIG. 2F). Subsequently, the outer-layer barrier insulating film 5b is formed on the inner-layer barrier insulating film 4b also by using the plasma CVD method (FIG. 2G).

In FIG. 2, a case of forming the copper-containing wirings 3a and 3b in the double-layer structure is described. However, it is possible to form the copper-containing wiring structure of more than two layers through repeating the processing shown in FIG. 2B-FIG. 2G. Further, in the explanations above, a dual damascene method which forms the wiring groove and the wiring hole simultaneously is used. However, the same is applied also when forming the wiring layer by using a single damascene method.

Next, a specific method for forming the outer-layer barrier insulating films 3a and 3b will be described by referring to FIG. 3. FIG. 3 shows a schematic view of the device for forming the outer-layer barrier insulating films 3a and 3b. In FIG. 3, a reserver 101 is a container which supplies a monomer raw material for forming the outer-layer barrier insulating films 3a and 3b. A raw material pressuring-out part 102 is for applying a pressure to send out the raw material within the reserver 101, and He is used as a pressurizing gas. A carrier gas supplying part 103 supplies carrier He for transporting the monomer raw material. A liquid massflow 104 controls a flow amount of the supplied raw material. A gas massflow 105 controls a flow amount of He as the carrier gas. A vaporizer 106 vaporizes the monomer raw material supplied from the reserver 101. A reactor 107 is a container for forming the outer-layer barrier insulating films 3a and 3b by using the vaporized monomer material through chemical vapor deposition.

As the monomer raw material, a material in a structure shown in a following Expression 1, for example, is used.

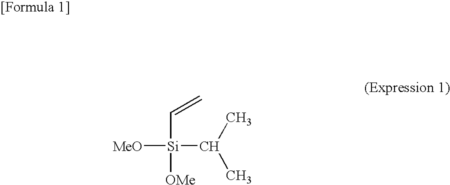

An RF power source 109 supplies a power for making the vaporized monomer raw material and the carrier gas (He) into plasma. A substrate 108 is a target to which the films are formed by chemical vapor deposition. An exhaust pump 110 discharges the raw material gas and the carrier gas introduced into the reactor 107.

A process of forming the outer-layer barrier insulating film 5a and 5b by using the device shown in FIG. 3 will be described below.

The monomer raw material is sent out from the reserver 101 by the He gas from the raw material pressuring-out part 102, and the flow amount thereof is controlled by the liquid massflow 104. In the meantime, the He gas is supplied from the carrier gas supplying part 103, and the flow amount thereof is controlled by the gas mass flow 105. The monomer raw material and He as the carrier gas are mixed right before the vaporizer 106, and supplied into the vaporizer 106.

There is a heated heater block (not shown) within the vaporizer 106, at which the liquid monomer raw material is vaporized, and it is supplied into the reactor 107. Within the reactor 107, the vaporized monomer material and the carrier gas are made into plasma by a high frequency of 13.56 MHz, and the outer-layer barrier insulating films 5a, 5b shown in FIG. 2 are formed on the substrate 109 by chemical vapor deposition.

When forming the outer-layer barrier insulating films 5a, 5b, the flow amount of the monomer raw material is preferable to be 0.5-2 g/min. More preferably, it is 0.8-1.5 g/min. The flow amount of He as the carrier gas is 100-1000 sccm. More preferably, it is 200-500 sccm. The pressure within the reactor 107 is 200 Pa-533 Pa. More preferably, it is 266 Pa-400 Pa. The output of the RF power source is 50-800 W. More preferably, it is 100-500 W.

FIG. 4 shows the result of evaluations obtained by Raman spectral analysis performed on the outer-layer barrier insulating films 5a and 5b formed by the above-described method by using the monomer shown with Expression (1) as the raw material.

As can be seen from FIG. 4, when Raman Shift taken as the lateral axis is in a range of 1200-1700 cm⁻¹, there are broad peaks P1, P2 and a peak P3 of a double linkage and hydrocarbon that may be generated because of amorphous carbon. The peaks P1 and P2 of amorphous carbon are in the vicinity of 1400 cm⁻¹ and 1600 cm⁻¹. In general, it is considered that the peak P1 in the vicinity of 1400 cm⁻¹ is generated because of Sp2-structure carbon, and the peak P2 in the vicinity of 1600 cm⁻¹ is generated because of Sp3-structure carbon. As described, it has been verified that the outer-layer barrier insulating films 5a and 5b formed by using the monomer shown with Expression (1) as the raw material contain amorphous carbon and unsaturated hydrocarbon from the result shown in FIG. 4 obtained by conducting Raman spectral analysis.

FIG. 5 shows the Cu diffusion resistant property of the outer-layer barrier insulating films 5a and 5b formed by using the monomer shown in Expression (1) as the raw material.

The evaluation of the Cu diffusion resistant property of the outer-layer barrier insulating films 5a, 5b was conducted by measuring a Cu distribution of depth directions with SIMS (Secondary Ion Mass Spectroscopy) after forming the outer-layer barrier insulating films 5a, 5b on the silicon substrate in a film thickness of 400 nm, plating the outer-layer barrier insulating films with Cu, and then applying heat treatment at 350 degrees C. for seven hours. SIMS analysis was conducted to check Cu distribution of the depth direction before and after the heat treatment through performing sputtering from the silicon substrate face in order to prevent Cu on the surface from being implanted with primary ions.

FIG. 5A is a depth direction profile before the heat treatment, and FIG. 5B is a depth direction profile after the heat treatment. From the result shown in FIG. 5, it is found that there is no change in the distribution for the depth directions of Cu before and after the heat treatment, and that the outer-layer barrier insulating films 5a, 5b formed by using the monomer shown in Expression (1) exhibit high Cu diffusion resistant property. Further, the measured relative dielectric constant of the outer-layer barrier insulating films 5a and 5b of the organic silica structure containing unsaturated hydrocarbon and amorphous carbon was 3.1.

Further, it is also found that the outer-layer barrier insulating films 5a, 5b exhibit high film strength, and have a high adhesive property with respect to the inner-layer barrier insulating films 4a, 4b. FIG. 6 shows a result of measurement, in which the outer-layer barrier insulating films 5a, 5b exhibit high film strength. The measurements were conducted by measuring the film strengths of the outer-barrier insulating films by using a nanointender after forming the outer-layer barrier insulating films 5a, 5b in a film thickness of 500 nm. FIG. 6 simultaneously shows the film strength of a typical SiOCH film and k-value, and it can be seen that the film strength of the outer-layer barrier insulating films 5a, 5b according to the first embodiment exhibit a value as high as 25 GPa.

Next, FIG. 7 shows a result of evaluating the adhesive strength of the outer-layer barrier insulating films 5a and 5b. The evaluation was conducted by using m-ELT to evaluate the adhesiveness after forming the films on SSiCN. FIG. 7 simultaneously shows the adhesive strength of a typical SiOCH film and k-value, and it can be seen that the adhesive strength of the outer-layer barrier insulating films 5a, 5b according to the first embodiment exhibit a value as high as 0.22 MPa·ml/2.

As described above, the outer-layer barrier insulating films according to the first embodiment exhibit not only high Cu diffusion resistant property but also a high film strength as well as high adhesiveness.

In the semiconductor device according to the first embodiment of the present invention, the barrier insulating films are formed in a double-layer structure with inner-layer barrier insulating films 4a, 4b for covering the surface of copper-containing wirings 3a, 3b and outer-layer barrier insulating films 5a, 5b stacked on the inner-layer barrier insulating films 4a, 4b, and the barrier insulating films 4a and 4b of a double-layer structure cover the copper-containing wirings 3a, 3b. Thus, the inner-layer barrier insulating films function as buffer layers for suppressing oxidation of the surfaces of the copper-containing wirings, when forming the outer-layer barrier insulating films. Therefore, together with the fact that the outer-layer barrier insulating films in the organic silica structure containing unsaturated hydrocarbon and amorphous carbon exhibit the Cu diffusion resistant property and that the relative dielectric constant thereof is less than 3.5, it enables reduction of the effective dielectric constant of the wirings. As a result, wiring signal delays can be improved.

Further, with the first embodiment, it is verified that the outer-layer barrier insulating films in the organic silica structure containing unsaturated hydrocarbon and amorphous carbon exhibit the Cu diffusion resistant property and that the relative dielectric constant thereof is less than 3.5. Thus, the inner-barrier insulating films may simply function as the buffer layers for preventing oxidation of the surfaces of the copper-containing wirings. Therefore, the film thickness of the inner-layer barrier insulating films can be set as thin as 5 nm or less, for example, which is in a range that can suppress oxidation of the surface of the copper-containing wiring. This makes it possible to reduce a volume taken up by the copper-containing wirings as much as possible.

### Second Embodiment

Next, as a second embodiment, there is described a case where SiN, SiCN, or SiC is used for the inner-layer barrier insulating films, and barrier insulating films of a double-layer structure having the inner-layer barrier insulating film and the outer-layer barrier insulating film are used.

FIG. 8 shows sectional views which are illustrated in order of manufacturing steps of a semiconductor device manufacturing method according to the second embodiment of the present invention. First, an SiO₂ film (insulating film) 11 of 300 nm is formed on a silicon substrate (not shown, and an SiCN film 12 of 30 nm in thickness as an etching stopper is formed on the SiO₂ film 11. Subsequently, a porous SiOCH film 13 in thickness of 80 nm with a relative dielectric constant of 2.55, which is to be an inter-wiring insulating film of a first wiring, is formed on the SiCN film 12 by a plasma CVD method. Thereafter, an SiO₂ film 14 in thickness of 120 nm as a hard mask for covering the surface of the porous low dielectric constant film is formed on the SiOCH film 13 also by the plasma CVD method (FIG. 8A).

The wiring grooves 1c are formed in the stacked insulating films by lithography and dry etching (FIG. 8B). Thereafter, a barrier metal film 15 of a TaN film and a Ta film as well as a Cu thin film of 40 nm is formed over the whole surface of the substrate by ionizing sputtering, and Cu 16 is embedded inside the wiring grooves 1 through electroplating by having the Cu film as an electrode (FIG. 8C).

Then, after applying heat treatment at 350 degrees C. for thirty minutes in a nitrogen atmosphere for growing Cu particles, extra Cu, Ta, TaN in each layer are removed by CMP. In addition, shaving is applied until the film thickness of the SiO₂ film 14 becomes about 30 nm, and a first wiring (copper-containing wiring) 16 is formed within the wiring grooves 1c with the remaining Cu 16 (FIG. 8D).

Next, an SiN (inner-layer barrier insulating film) 17 of a film thickness of 5 nm is formed on the entire surface of the substrate by the plasma CVD method (FIG. 8E). Thereafter, an outer-layer barrier insulating film 18 in a thickness of 25 nm in an organic silica structure having the Cu diffusion resistant property is formed on the SiN film 17 by the plasma CVD method by using isopropyl vinyl dimethoxy silane as a raw material (FIG. 8F). At this time, oxygen is contained in a film-forming gas for forming the outer-layer barrier insulating film 18. However, the surface of the first wiring 16 made with Cu is covered by the SiN film 17 as the inner-layer barrier insulating film, so that oxidation of the surface of the first wiring 16 can be suppressed.

Furthermore, as a via wiring interlayer insulating film, a porous SiOCH film 19 having a relative dielectric constant of 2.8 is formed in 100 nm by the plasma CVD method. Then, as an inter-wiring insulating film in a second wiring layer, a porous SiOCH film 20 having a relative dielectric constant of 2.25 is formed in 110 nm by the plasma CVD method, and an SiO₂ film 21 to be a hard mask is formed in 120 nm by the plasma CVD method (FIG. 8G).

A part of the SiO₂ film 21, a part of the porous SiOCH film 20, and a part of the porous SiOCH film 19 are removed in order through lithography and anisotropic dry etching by using the outer-layer barrier insulating film 18 as an etching stopper to form a via hole 1e between the first wiring layer and the second wiring layer (FIG. 8H). The outer-layer barrier insulating film 18 and the via wiring interlayer insulating film 19 are both in the organic silica structure (SiOCH). However, composite ratios of C/Si are different, so that a selecting ratio at the time of performing dry etching can be secured.

Continuously, a part of the hard mask 21 and a part of the inter-wiring insulating film 20 are removed to form the wiring groove 1c of the second wiring layer through lithography and anisotropic dry etching. At the same time, the outer-layer barrier insulating film 18 and the inner-layer barrier insulating film 17 in the bottom part of the via hole are removed to expose the upper connecting surface of the first wiring layer (FIG. 8I). Etching residuals in the via hole and the groove and CuO, Cu₂O on the Cu surface exposed in the via bottom are removed by using an organic stripper.

Then, a Cu film in 40 nm and a barrier metal film 22 in which a TaN film and a Ta film are stacked in this order are formed by an ionizing sputtering method through the same procedure as the case of forming the first wiring layer so as to cover the inner face of wiring groove of the second wiring and the inner face of the via hole between the first wiring layer and the second wiring layer, and Cu 23 is embedded by electroplating by using the formed films as seed electrodes (FIG. 8J).

Then, as in the case of forming the first wiring layer, heat treatment is applied at 350 degrees C. for thirty minutes in a nitrogen atmosphere for growing Cu particles. Thereafter, extra Cu, Ta, TaN in each layer are removed. In addition, shaving is applied until the film thickness of the SiO₂ hard mask film becomes about 30 nm to form a second wiring (copper-containing wiring) 23 (FIG. 8K).

Next, as in the case where the first wiring layer has been formed, an SiN (inner-layer barrier insulating film) 24 of a thickness of 5 nm is formed as a first barrier insulating film on the entire surface by the plasma CVD method (FIG. 8I). Thereafter, an outer-layer barrier insulating film 25 in a thickness of 25 nm in an organic silica structure having the Cu diffusion resistant property is formed on the inner-layer barrier insulating film 24 by the plasma CVD method by using isopropyl vinyl dimethoxy silane as a raw material (FIG. 8M). Further, an SiO₂ film 26 is formed as a cover film (FIG. 8N).

After opening a junction part with respect to the second wiring layer in the cover film 26 through lithography and etching, Ti, TiN, and Al are deposited in order by sputtering. The Al/TiN/Ti stacked film is processed to a pad pattern for measuring electricity through lithography and etching.

FIG. 9 is a chart of a comparison between the effective dielectric constant of the structure shown in the above-described second embodiment and the effective dielectric constant of a general-purpose structure. Compared to the typically used barrier insulating film structure of SiCN=30 nm, it can be seen that the effective dielectric constant is reduced by 4.5% by using the stacked-type barrier insulating film structure which employs the organic silica structure in a film thickness of 25 nm as the outer-layer barrier insulating film and uses the SiN film in a film thickness of 5 nm as the inner-layer barrier insulating film as described in the second embodiment.

While the SiN was used as the inner-layer barrier insulating film, it has also been verified that the effective dielectric constant was reduced in the same manner as in FIG. 9 when SiCN or SiC was used instead of SiN. As can be seen from FIG. 9, the effective dielectric constant can be reduced by about 6.2%, in the case of the stacked-type inner-layer and outer-layer barrier insulating films (organic silica/SiCN) which uses the SiCN film for the inner-layer barrier insulating film.

### Third Embodiment

Next, a case where the copper-containing wiring has a modified layer or a metal cap will be described as a third embodiment.

As shown in FIG. 10, the third embodiment has modified layers 6a, 6b containing a large amount of impurities, which are formed on the surface of the copper-containing wirings 3a, 3b. Alternatively, as shown in FIG. 11, the third embodiment has metal cap layers 7a, 7b formed on the surface of the copper-containing wirings 3a, 3b.

In a case shown in FIG. 10, the copper-containing wiring 3a covered by the barrier metal 2a is formed in the insulating film 1a, the Cu surface modified layer 6a is stacked on the top part of the copper-containing wiring 3a, and the barrier insulating film 5a of the organic silica component containing unsaturated hydrocarbon and amorphous carbon is further stacked on the Cu surface modified layer 6a. Furthermore, the insulating film 1b is stacked on the barrier insulating film 5a, the copper-containing wiring 3b covered by the barrier metal 2b is formed in the insulating film 1b, the Cu surface modified layer 6b is stacked on the top part of the copper-containing wiring 3b, and the barrier insulating film 5b of the organic silica component containing unsaturated hydrocarbon and amorphous carbon is further stacked on the Cu surface modified layer 6b.

In the case of FIG. 10, a compound of an organic silica structure made with SiOCH is used for the barrier insulating films 5a and 5b. Further, while the copper-containing wirings 3a and 3b are formed in two steps (upper and lower steps) in FIG. 10, the number of stacked layers of the copper-containing wirings is not limited only to “2” as in the case shown in FIG. 10.

In a case shown in FIG. 11, the copper-containing wiring 3a covered by the barrier metal 2a is formed in the insulating film 1a, the metal cap layer 7a is stacked on the surface of the copper-containing wiring 3a, and the barrier insulating film 5a of the organic silica component containing unsaturated hydrocarbon and amorphous carbon is further stacked on the metal cap layer 7a. Furthermore, the insulating film 1b is stacked on the barrier insulating film 5a, the copper-containing wiring 3b covered by the barrier metal 2b is formed in the insulating film 1b, the metal cap layer 7b is stacked on the surface of the copper-containing wiring 3b, and the barrier insulating film 5b of the organic silica component containing unsaturated hydrocarbon and amorphous carbon is further stacked on the metal cap layer 7b.

In the case of FIG. 11, a compound of an organic silica structure made with SiOCH is used for the barrier insulating films 5a and 5b. Further, while the copper-containing wirings 3a and 3b are formed in two steps (upper and lower steps) in FIG. 11, the number of stacked layers of the copper-containing wirings is not limited only to “2” as in the case shown in FIG. 11.

As described above, the modified layer having the oxidation resistant property (FIG. 10) or the metal cap layer (FIG. 11) is formed on the Cu surface as the oxidation preventing layer for suppressing oxidation of the surface of the copper-containing wiring by O contained in the film-forming gas when forming the organic silica film having the Cu diffusion resistant property, and the barrier insulating films 5a and 5b of the organic silica structure having the Cu diffusion resistant property are formed thereon.

Next, the semiconductor device shown in FIG. 10, i.e., the case of forming the modified layer having the oxidation resistant property on the copper-containing wiring, will be described by referring to FIG. 12.

In FIG. 12A, the copper-containing wiring 3a covered by the barrier metal 2a is formed in the insulating film 1a, the Cu surface modified layer 6a is formed on the surface of the copper-containing wiring 3a, and the barrier insulating film 5a is formed on the Cu surface modified layer 6a. The structure described in FIG. 12A is formed through a process that is the same process described in FIG. 12B and thereafter.

First, the insulating film 1b is formed on the barrier insulating film 5a (FIG. 12B), and lithography and anisotropic etching are performed thereafter to form the wiring groove 1c and the wiring hole 1d in the insulating film (FIG. 12C). Then, the barrier metal film 2b is formed on the inner walls of the wiring groove 1c and the wiring hole 1d, and Cu 3b is deposited on the barrier metal insulating film 2b to be embedded inside the wiring groove 1c and the wiring hole 1d (FIG. 12D). Subsequently, heat treatment is applied for growing Cu particles. The temperature of the heat treatment is set to 200 degrees C.-400 degrees C., and the time thereof is set to 30 seconds-1 hour.

Then, extra Cu and barrier metal are removed by using a polishing technique such as CMP (FIG. 12E). Next, an SiH₄ gas is irradiated onto the surface within a vacuum chamber by setting the substrate temperature within a range of 200 degrees C.-350 degrees C. to form CuSi on the surface of the copper-containing wiring 1b. Subsequently, NH₃ plasma is irradiated within the same chamber to form the surface modified layer 6b made with CuSiN on the surface of the copper-containing wiring 3b (FIG. 12F). Thereafter, the harrier insulating film 6h of the organic silica structure having the Cu diffusion resistant property and the relative dielectric constant of less than 3.5 is formed through the plasma CVD method described in the first embodiment (FIG. 12G). Through repeating FIG. 12B-12G, a still upper-side wiring layer can be formed. Further, in the explanations above, a dual damascene method which forms the wiring groove and the wiring hole simultaneously is used. However, the same is applied also when forming the wiring layer by using a single damascene method.

Next, the semiconductor device shown in FIG. 11, i.e., the case of forming the metal cap layer on the copper-containing wiring, will be described by referring to FIG. 13.

In FIG. 13A, the copper-containing wiring 3a covered by the barrier metal 2a is formed in the insulating film 1a, the metal cap layer 6a is formed on the top part of the copper-containing wiring 3a, and the barrier insulating film 5a is formed on the metal cap layer 6a. The structure described in FIG. 13A is formed through a process that is the same process described in FIG. 13B and thereafter.

First, the insulating film 1b is formed on the barrier insulating film 5a (FIG. 13B), and lithography and anisotropic etching are performed thereafter to form the wiring groove 1c and the wiring hole 1d in the insulating film (FIG. 13C). Then, the barrier metal film 2b is formed on the inner walls of the wiring groove 1c and the wiring hole 1d, and Cu 3b is deposited on the barrier metal insulating film 2b to be embedded inside the wiring groove 1c and the wiring hole 1d (FIG. 13D). Subsequently, heat treatment is applied for growing Cu particles. The temperature of the heat treatment is set to 200 degrees C.-400 degrees C., and the time thereof is set to 30 seconds-1 hour. Next, the extra Cu and the barrier metal are removed by using a polishing technique such as CMP to form the copper-containing wiring 3b (FIG. 13E). Then, the metal cap layer 7b of CoWP, for example, is formed selectively on the surface of the copper-containing wiring 3b by using an electroless plating method (FIG. 13F).

Thereafter, the barrier insulating film 7b of the organic silica structure having the Cu diffusion resistant property and the relative dielectric constant of less than 3.5 is formed through the plasma CVD method described in the first embodiment (FIG. 13G). Through repeating FIG. 13B-13G, a still upper-side wiring layer can be formed. The metal cap layer is formed by the electroless plating method, and it may be formed with COWB, CoSnP, CoSnB, NiB, or NiMoB, other than with CoWP. Further, in the explanations above, a dual damascene method which forms the wiring groove and the wiring hole simultaneously is used. However, the same is applied also when forming the wiring layer by using a single damascene method.

In the third embodiment of the present invention, the surfaces of the copper-containing wirings 3a, 3b are covered by the surface modified layer or the metal cap layers 6a, 6b. Therefore, it is possible to prevent the surfaces of the copper-containing wirings 3a, 3b from being oxidized, when forming the barrier insulating films 7a, 7b.

Further, with the third embodiment, it is not necessary to use the inner-layer barrier insulating films 4a, 4b of SiN, SiCN, or the like, when there are the surface modified layers or the metal cap layers 7a, 7b having the oxidation resistant property formed on the surfaces of the copper-containing wirings 3a, 3b. With the third embodiment, the effective relative dielectric constant can be reduced by 7.6% as in FIG. 9 by using the barrier insulating films 7a, 7b in a film thickness of 30 nm of the organic silica structure with the relative dielectric constant of 3.1, compared to the case of using the typically-used barrier insulating film structure in which the SiCN film is in a thickness of 30 nm.

Next, a case of forming a barrier insulating film on the surface modified layers or the metal cap layers formed on the surfaces of the copper-containing wirings 3a, 3b will be described as a fourth embodiment.

### Fourth Embodiment

In the fourth embodiment, the modified layers 6a, 6b (FIG. 14) or the metal cap layers 6a, 6b having the oxidation resistant property (FIG. 15) are provided as the oxidation preventing layers for suppressing oxidation of the surface of the copper-containing wiring by O contained in the film-forming gas when forming the organic silica film (barrier insulating film) having the Cu diffusion resistant property, the inner-layer barrier insulating films 4a, 4b of a film thickness of less than 5 nm made with SiN, SiCN, or SiC are provided thereon, and the organic silica films having the Cu diffusion resistant property are formed thereon further as the barrier insulating films 5a and 5b.

Next, the semiconductor device shown in FIG. 14, particularly the wiring structure, will be described by referring to FIG. 16. FIG. 16 shows a case of forming the modified layers 6a, 6b having the oxidation resistant property on the surfaces of the copper-containing wirings 3a, 3b.

In FIG. 16A, the copper-containing wiring 3a covered by the barrier metal 2a is formed in the insulating film 1a, the Cu surface modified layer 6a is stacked on the top part of the copper-containing wiring 3a, and the inner-layer barrier insulating film 5a is formed on the Cu surface modified layer 6a. The structure shown in FIG. 16A is formed through a process that is the same process described in FIG. 16B and thereafter.

First, the insulating film 1b is formed on the barrier insulating film 1a (FIG. 16B), and lithography and anisotropic etching are performed thereafter to form the wiring groove 1c and the wiring hole 1d in the insulating film (FIG. 16C). Then, the barrier metal film 2b is formed on the inner walls of the wiring groove 1c and the wiring hole 1d, and Cu 3b is deposited on the barrier metal insulating film 2b to be embedded inside the wiring groove 1c and the wiring hole 1d (FIG. 16D). Subsequently, heat treatment is applied for growing Cu particles. The temperature of the heat treatment is set to 200 degrees C.-400 degrees C., and the time thereof is set to 30 seconds-1 hour. Then, extra Cu and barrier metal are removed by using a polishing technique such as CMP to form the copper-containing wiring 3b (FIG. 16E).

Next, SiH₄ gas is irradiated onto the surface within a vacuum chamber by setting the substrate temperature within a range of 200 degrees C.-350 degrees C. to form CuSi on the surface of the copper-containing wiring 3b. Further, NH₃ plasma is irradiated within the same chamber to form the surface modified layer 6b made with CuSiN (FIG. 16F). Subsequently, the inner-layer barrier insulating film 4b made with SiN, SiCN, or SiC is formed by the plasma CVD method within the same chamber (FIG. 16G). Thereafter, the outer-layer barrier insulating film 5b of the organic silica structure having the Cu diffusion resistant property and the relative dielectric constant cf less than 3.5 is formed on the inner-layer barrier insulating film 4b through the plasma CVD method described in the first embodiment (FIG. 16H). Through repeating FIG. 16B-16H, a still upper-side wiring layer can be formed. Further, in the explanations above, a dual damascene method which forms the wiring groove and the wiring hole simultaneously is used. However, the same is applied also when forming the wiring layer by using a single damascene method.

The use of a composite gas cluster ion beam of the SiH₄ gas and N₂ gas or NH₃ gas, for example, makes it possible to execute the processing for forming the modified layer 6b on the surface of the copper-containing wiring 3b (FIG. 16F) and the processing for forming the inner-layer barrier insulating film 4b (FIG. 16G) collectively. More specifically, the composite gas cluster ion beam is irradiated on the surface of the wafer to form the modified layers 6a, 6b and the inner-layer barrier films 4a, 4b on the surfaces of the copper-containing wirings 3a, 3b. When the irradiation time of the gas cluster ion beam irradiated on the copper-containing wirings 3a, 3b is short, the modified layers 6a, 6b of CuSiN are formed in an extremely shallow part at a depth of several nm. This is because the cluster size is large, so that the energy per atom is normally 5 eV or less even if an acceleration energy is high. Thus, it is hard for the ion beams to be implanted into the depth direction. When the irradiation is continued in this state, not only the modified layers 6a, 6b but also the inner-layer barrier insulating films 4a, 4b of SiN are formed on the surfaces of the copper-containing wirings 3a, 3b. The thickness of the modified layers 6a and 6b can be controlled by changing the acceleration voltage and the substrate temperature.

Next, the semiconductor device shown in FIG. 15, particularly the wiring structure, will be described by referring to FIG. 17. FIG. 17 shows a case of forming the metal cap layers 6a, 6b having the oxidation resistant property on the surfaces of the copper-containing wirings 3a, 3b.

In FIG. 17A, the copper-containing wiring 3a covered by the barrier metal 2a is formed in the insulating film 1a, the metal cap layer 6a is formed on the surface of the copper-containing wiring 3a, and the inner-layer barrier insulating film 5a is formed on the metal cap layer 6a. The structure described in FIG. 17A is formed through a process that is the same process described in FIG. 17B and thereafter.

First, the insulating film 1b is formed on the barrier insulating film 1a (FIG. 17B), and lithography and anisotropic etching are performed thereafter to form the wiring groove 1c and the wiring hole 1d in the insulating film (FIG. 17C). Then, the barrier metal film 2b is formed on the inner walls of the wiring groove 1c and the wiring hole 1d, and the Cu 3b is deposited on the barrier metal insulating film 2b to be embedded inside the wiring groove 1c and the wiring hole 1d (FIG. 17D). Subsequently, heat treatment is applied for growing Cu particles. The temperature of the heat treatment is set to 200 degrees C.-400 degrees C., and the time thereof is set to 30 seconds-1 hour. Then, extra Cu and barrier metal are removed by using a polishing technique such as CMP to form the copper-containing wiring 3b (FIG. 17E).

Then, the metal cap layer 7b of COWP, for example, is formed selectively on the surface of the copper-containing wiring 3b by using an electroless plating method (FIG. 17F). Subsequently, the inner-layer barrier insulating film 4b made with SiN, SiCN, or SiN is formed on the metal cap layer 7b by the plasma CVD method (FIG. 17G). Thereafter, the barrier insulating film 5b of the organic silica structure having the Cu diffusion resistant property and the relative dielectric constant of less than 3.5 is formed on the metal cap layer 7b through the plasma CVD method described in the first embodiment (FIG. 17H). Through repeating FIG. 17B-17H, a still upper-side wiring layer can be formed. The metal cap layers 7a, 7b are formed with CoWP by the electroless plating method. However, the metal cap layers 7a, 7b may also be formed with COWB, CoSnP, CoSnB, NiB, or NiMoB. Further, in the explanations above, a dual damascene method which forms the wiring groove and the wiring hole simultaneously is used. However, the same is applied also when forming the wiring layer by using a single damascene method.

### Fifth Embodiment

FIG. 18 shows sectional views of the copper-containing wiring according to a fifth embodiment of the present invention. As shown in FIG. 18, in the fifth embodiment, a copper-containing wiring 43a covered by a barrier metal 42a is formed in an insulating film 41, a modified layer 44a is formed on the surface of the copper-containing wiring 43a, a barrier insulating film 45a is formed on the modified layer 44a, and a via insulating film 46 and a trench insulating film 47 are stacked on the barrier insulating film 45a. Further, a copper-containing wiring 43h covered by a barrier metal 42b is formed in the trench insulating film 47, and a part of the copper-containing wiring 43b is electrically connected to the lower-layer copper-containing wiring 43a through the via of the via insulating film 46. Further, a modified layer 44b is formed on the surface of the upper-layer copper-containing wiring 43b, and a barrier insulating film 45b is formed on the modified layer 44a.

In the fifth embodiment, the modified layers 44a, 44b function as the oxidation preventing layers for suppressing oxidation of the surfaces of the copper-containing wirings 43a, 43b by contained in the film-forming gas, when forming the barrier insulating films 45a, 45b of the organic silica structure having the Cu diffusion resistant property. Then, the barrier insulating films 45a, 45b of the organic silica structure having the Cu diffusion resistant property are formed on the modified layers 44a, 44b having the oxidation resistant property.

Next, a method for manufacturing the wiring structure of the fifth embodiment shown in FIG. 18 will be described by referring to FIG. 19. FIG. 19 shows an enlarged state of a copper-containing wiring 30 which corresponds to the copper-containing wirings 43a and 43b. After performing CMP, an extremely thin oxide film CuOₓ 31 is formed on the surface of the copper-containing wiring 30 (FIG. 19A).

An anticorrosive agent 32 is applied on the CuOₓ 31 for preventing further oxidation (FIG. 19B). Then, heat treatment is applied in an N₂ atmosphere before forming the modified layers having the oxidation resistant property to remove the anticorrosive agent 32 (FIG. 19C). At this time, the extremely thin oxide film CuOₓ 31 is not removed and remained on the surface of the copper-containing wiring 30 (FIG. 19C). Thereafter, a barrier insulating film 33 made with SiN, SiCN, or SIC is formed by the plasma CVD method in a same chamber (FIG. 19D).

By having the surface of the copper-containing wiring 30 exposed to the SlH₄ gas when forming the barrier insulating film 33, Si starts to diffuse from the surface of the copper-containing wiring 30 towards the inside. However, Si diffusion is hindered by the existence of the CuOₓ 31, and Si is accumulated in the vicinity of the surface of the copper-containing wiring 30. Therefore, a fine oxygen diffusion barrier film 33 is formed without having a noticeable increase in the wiring resistance, so that the oxidation resistant property can be improved (FIG. 19D). More preferably, the oxygen diffusion barrier film 33 may be deoxidized by NH₃ plasma, and a modified layer 34 with a high oxidation resistant property made with Cu—Si—N may be formed on the surface of the copper-containing wiring 30 (FIG. 19C).

Further, the oxidation resistant property may be improved by forming a nitride on the outermost surface while deoxidizing the CuOₓ 31 through performing surface processing by NH₃ plasma after applying heat treatment in an N₂ atmosphere. Furthermore, the oxidation resistant property may be improved by exposing the surface to SiH₄ gas after applying heat treatment in an N₂ atmosphere and then terminating Cu active sites by NH₃ plasma. Alternatively, the modified layer may be formed by exposing the surface to a mixed gas of SiH₄ and NH₃ after performing heat treatment in an N₂ atmosphere to deoxidize/remove the CuOₓ layer on the outermost surface and by adding Si to the Cu surface at the same time.

Moreover, a modified layer with a high oxidation resistant property may be formed through a step of irradiating composite gas cluster ions containing SiH₄ and at least one kind selected from NH₃, N₂, CH₃, C₂H₂, and C₂H₄.

A barrier insulating film is formed by using the plasma CVD method on the modified layer having a high oxidation resistant property which is formed in the manner described above. Hereinafter, a step of forming an upper-layer wiring will be described by referring to FIG. 20A. In FIG. 20A, the copper-containing wiring 43a covered by the barrier metal 42a is formed in the insulating film 41, and the modified layer 44a and the barrier insulating film 45a are formed on the surface of the copper-containing wiring 43a.

The via insulating film 46, the trench insulating film 47, and the hard mask 48 were formed on the barrier insulating film 45 in order (FIG. 21B). Those films may be formed separately by using individual devices, or the barrier insulating film 45a, the via insulating film 46, the trench insulating film 47, and the hard mask 48 may be formed continuously by using a same chamber.

FIG. 34 is a schematic diagram showing an example of a plasma CVD device for forming the barrier insulating film 45a, the via insulating film 46, the trench insulating film 47, and the hard mask 40 of the fifth embodiment of the present invention. A plasma CVD device 250 shown in FIG. 34 has a reaction chamber 210, a gas supplying part 220, a vacuum pump 230, and a high-frequency power source 240. The gas supplying part 220 is connected to the reaction chamber 210 via a gas supplying pipe 222, and the vacuum pump 230 is connected to the reaction chamber 210 via a gas exhaust pipe 236 having a valve 232 and a cooling trap 234 disposed in the middle thereof. Further, the high-frequency power source 240 is connected to the reaction chamber 210 via a high-frequency cable 244 having a matching box 242 disposed in the middle thereof.

Within the reaction chamber 210, a substrate heating part 203 (which holds/heats a film-forming member 201) and a shower head 205 (which functions as a gas ejection part to which one end of the gas supplying pipe 222 is connected) are arranged to oppose each other. An earth line 207 is connected to the substrate heating part 203, and a high-frequency cable 244 is connected to the shower head 205. Therefore, the gas in a space between the substrate heating part 203 and the shower head 205 can be made into plasma through supplying a raw material gas and the like from the gas supplying part 220 to the shower head 205 via the gas supplying pipe 222 and by supplying high-frequency power generated by the high-frequency power source 240 to the shower head 205 after making it into a prescribed frequency by the matching box 242 disposed in the middle of the high-frequency cable 244.

A cleaning gas supplying pipe 228 having a flow amount controller 224 and a valve 226 disposed in the middle thereof is connected to the gas supplying pipe 222. A drain pipe 238 is provided by being branched from the gas exhaust pipe 236 at an area between the valve 232 and the cooling trap 234. It is preferable to heat the gas supplying pipe 222 by providing a heater (not shown) in the periphery of the gas supplying part 222 for preventing each gas from becoming liquid in a process of transportation. Similarly, it is preferable to heat the reaction chamber 210 by providing a heater (not shown) also in the periphery of the reaction chamber 210.

FIG. 35 shows the inside of the gas supplying part 220. Vaporization control units VU1 and VU2 have: a raw material tank 302 which stores liquid organic siloxane materials 301, 303; a pressuring gas supplying device 306 which supplies a pressuring gas to the inside the raw material tank 302 via the pressuring gas supplying pipe 304; a raw material transporting pipe 308 whose one end is inserted to the inside the raw material tank 302; a liquid flow amount control part 310 provided in the middle of the raw material transporting pipe 308; and a vaporizing part 312 disposed on the other-end side of the raw material transporting pipe 308. The above-described liquid flow amount control part 310 has two valves 310a, 310b, and a liquid flow amount controller 310c disposed between the valves 310 and 310b. The above-described vaporizing part 312 has a valve 312a provided on the aforementioned other-end side of the raw material transporting pipe 308, and a vaporizer 312b connected to the aforementioned other end of the raw material transporting pipe 308.

Further, each of the vaporization control units VU1 and VU2 has: a gas supplying tank 314 (referred to as “carrier gas supplying tank” hereinafter) for a carrier gas or a dilute gas; and a pipe 316 provided between the liquid flow amount control part 310 and the vaporizing part 312 to supply the carrier gas or the dilute gas within the carrier gas supplying tank 314 to the raw material compound transporting pope 308. A gas flow amount control part 318 having two valves 318a, 318b and a gas flow amount controller 318c disposed between the two valves 318a, 318b is provided in the middle of the pipe 316. In the vaporization control unit Vu1, when the pressuring gas is supplied to the inside the raw material tank 302 from the pressuring gas supplying device 306 via the pressuring gas supplying pipe 304, the internal pressure of the raw material tank 302 is increased. Thereby, the first organic siloxane raw material 301 in a liquid form within the raw material tank 302 is transported towards the vaporizing part 312 via the raw material transporting pipe 308, and mixed with the carrier gas or the dilute gas on the way to reach the vaporizing part 312. The liquid organic siloxane raw material 301 that has reached the vaporizing part 312 is vaporized because of reduction in the pressure at an introductory part of the vaporizing part 312 and heat applied by the heater (not shown).

Similarly, in the vaporization control unit VU2, when the pressuring gas is supplied to the inside the raw material tank 302 from the pressuring gas supplying device 306 via the pressuring gas supplying pipe 304, the internal pressure of the raw material tank 302 is increased. Thereby, the second organic siloxane raw material 303 in a liquid form within the raw material tank 302 is transported towards the vaporizing part 312 via the raw material transporting pipe 308, and mixed with the carrier gas or the dilute gas on the way to reach the vaporizing part 312. The liquid cyclic organic siloxane raw material 301 that has reached the vaporizing part 312 is vaporized because of reduction in the pressure at an introductory part of the vaporizing part 312 and heat applied by the heater (not shown).

Further, it is also possible to introduce two kinds or more of organic silica materials to the inside the raw material tank 302 of the vaporization control unit VU1, and to vaporize the materials simultaneously in the vaporizing part 312 of the vaporization control unit VU1 without using the vaporization control unit VU2.

For smoothly performing vaporization in each vaporizer 312b, it is preferable to provide the heater in the periphery of the raw material compound transporting pipe 308 on the lower stream side than the valve 310c of the liquid flow amount control part 310 and to heat the raw material compound transporting pipe 308. Similarly, for preventing each gas from becoming liquid, it is preferable to provide the heater in the periphery of each of gas exhaust pipes 320, 352 and a mixer 340 to heat each of those gases.

As a method for forming an organic silicon film by using the plasma CVD device 250, the film-forming member 201 such as a semiconductor substrate is placed on the substrate heating part 203, and the vacuum pump 230 is activated while opening the valve 232 to bring an initial vacuum degree within the reaction chamber 210 to several Torr. The moisture in the gas discharged from the reaction chamber 210 is removed by the cooling trap 234. Then, the raw material gas (gaseous cyclic organic siloxane gas) is supplied from the gas supplying part 220 to the reaction chamber 210 along with the carrier gas or the dilute gas. At the same time, the high-frequency power source 240 and the matching box 242 are activated to supply a high-frequency power of a prescribed frequency to the reaction chamber 210.

At this time, the flow amount of each gas is controlled by the corresponding flow amount control part 318 to generate a mixed gas of a prescribed composition at the mixer 340, and it is supplied to the reaction chamber 210. It is preferable to appropriately select a partial pressure of the raw material gas in the reaction chamber 210 to be in a range of about 13-400 Pa. Further, it is preferable to set an atmospheric pressure in the reaction chamber 210 at the time of forming the film to be within a range of about 133-1333 Pa by controlling the operation of the vacuum pump 230. The surface temperature of the film-forming member 201 at the time of forming the film can be set appropriately within a range of 100-400 degrees C. by heating the film-forming member 1 by using the substrate heating part 3. More specifically, the surface temperature is preferable to be within a range of 250-350 degrees C. As has been described above, depending on the kinds of the compound raw material to be used, it is supplied to the reaction chamber 210 prior to supplying the raw material gas.

When the film is formed under such condition, molecules of the cyclic organic siloxane raw material as a raw material gas are excited by plasma, and the molecules in an activated state reach the surface of the film-forming member 201 to form an insulating film there. When the insulating film includes a radical having unsaturated linkages, the molecules of the organic silicon compound activated by being excited by the plasma reach the surface of the film-forming member 1 and receives a heat energy further from the substrate heating part 3. Therefore, the unsaturated linkages in the radical are opened, and a thermal polymerization between the molecules advances, thereby growing the insulating film.

For cleaning the reaction chamber 210, it is possible to use a gas such as trifluoride nitrogen (NF₃), hexafluoride sulfur (SF₆), tetrafluoro methane (CF₄), hexafluoro ethane (C₂F₆), or the like. Those gases may be used as a mixed gas by being mixed with an oxygen gas, an ozone gas, or the like as necessary. The cleaning gas is supplied to the reaction chamber 210 via the cleaning gas supplying pipe 228. As in the case of forming the film, a high-frequency power is applied between the shower head 205 and the substrate heating part 3 to induce plasma for performing cleaning of the reaction chamber 210. It is also effective to use a cleaning gas that is put into a plasma state in advance by using remote plasma or the like.

In this embodiment, the film is formed by using a raw material having a cyclic organic siloxane structure shown in Expression 2 stored within the raw material tank 302 of the vaporization control unit VU1 and a raw material having a straight-chain organic siloxane structure shown in Expression 4 stored within the raw material tank 302 of the vaporization control unit VU2.

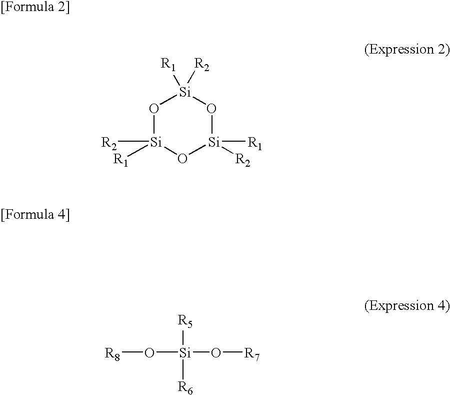

Thereafter, lithography and anisotropic etching are performed to form the wiring groove 1c and the wiring hole 1d in the insulating films 46 and 47 (FIG. 20C). Then, the barrier metal 42b is formed on the inner walls of the wiring groove 1c and the wiring hole 1d, and Cu 43b is deposited on the barrier metal insulating film 42b to be embedded inside the wiring groove 1c and the wiring hole 1d (FIG. 20D). Subsequently, heat treatment is applied for growing Cu particles. The temperature of the heat treatment is set to 200 degrees C.-400 degrees C., and the time thereof is set to 30 seconds-1 hour. Then, extra Cu and barrier metal are removed by using a polishing technique such as CMP to form the copper-containing wiring 43b, then the modified layer 44b with a high oxidation resistant property is formed on the surface of the copper-containing wiring 43b, and the barrier insulating film 45a is formed thereon (FIG. 20E).

Next, the semiconductor device according to the fifth embodiment of the present invention will be described in detail. FIG. 21 shows spectra of a mass number 78 obtained by applying heat treatment in an N₂ atmosphere after applying the anticorrosive agent 32 on the copper-containing wiring and CuOₓ, and by performing a thermal deposition analysis on the residual state of the anticorrosive agent 32 remained on the surface. FIG. 22A shows the state before applying the heat treatment in the N₂ atmosphere, and FIG. 22B shows the result after ten seconds from the heart treatment applied in the N₂ atmosphere. A peak observed in the vicinity of the point at 250 degrees C. in FIG. 22A is generated due to the anticorrosive agent 32, and it can be seen that the anticorrosive agent can be removed when the heat treatment in the N₂ atmosphere is performed at 250 degrees C. or higher. FIG. 22 illustrates plotting of the peak area in the vicinity of the point at 250 degrees C. with respect to the heat treatment time, which shows a case of performing the heat treatment in vacuum with respect to the case in the N₂ atmosphere. In the N₂ atmosphere, it was possible to remove the anticorrosive agent by applying the heat treatment of ten seconds or longer, whereas it was not possible to remove the anticorrosive agent in vacuum even with the heat treatment of sixty seconds. Thus, superiority of N₂ atmosphere heat treatment was recognized.

FIG. 23 illustrates plotting of changes in the sheet resistance with respect to the flow amount of SiH₄, after performing the heat treatment in the N₂ atmosphere, irradiating SiH₄, performing NH₃ plasma processing for forming the modified layer having the oxidation resistant property on the surface of the copper-containing wiring, and then exposing the substrate in a high-temperature state in the air for forcible oxidization.

When the anticorrosive agent is removed by the heat treatment in the N₂ atmosphere, an extremely-thin CuOₓ film is remained on the outermost surface of the copper-containing wiring. This makes it possible to suppress diffusion of Si into the inside the copper-containing wiring by irradiation of SiH₄. It is considered that a notable increase in the sheet resistance by irradiation of SiH₄ can therefore be suppressed. In the meantime, Si atoms accumulated on the surface of the copper-containing wiring are made into nitride by NH₃ plasma processing, and the modified layer of a high oxidation resistant property is formed. Thereby, diffusion of oxygen into the inside the copper-containing wiring can be suppressed. FIG. 24 shows a result of oxygen concentration at the depth of 5 nm from the surface of a same sample obtained by an X-ray photoelectronic spectroscopy analysis. From this result, it can be seen that diffusion of oxygen is suppressed by irradiation of SiH₄. This effect can be recognized from the point where the flow amount of SiH₄ is 25 sccm, and it can be seen that oxidation is completely suppressed at the point of 100 sccm and more. As has been described above, this surface processing makes it possible to form the modified layer having a high Cu oxidation resistant property with only a small increase in the sheet resistance of the copper-containing wiring.

As described, the modified layer having the oxidation resistant property is formed by irradiation of SiH₄. It is also possible to form the modified layer having the oxidation resistant property containing Cu, Si, N on the surface by using a mixed gas of SiH₄ and NH₃.

By using the method shown in the fifth embodiment, the barrier insulating film was formed on the modified layer having the high oxidation resistant property that is formed in the manner described above. FIG. 25 shows Cu diffusion in the via insulating film, which was measured by using a secondary ion mass analysis (SIMS analysis) method conducted regarding the Cu diffusion barrier characteristic of the barrier insulating film formed in the manner described above. It was verified that Cu diffusion was suppressed as in the case of a normally used SiCN harrier. Further, FIG. 26 is a graph showing a current-voltage characteristic of the barrier insulating film formed in the manner described above. It was verified that a leak current was lower and a withstanding pressure was higher compared to the case of the normal SiCN barrier.

Further, the second barrier insulating film 45a, the via insulating film 46, the trench insulating film 47, and the hard mask 48 were formed continuously within a same chamber. The second insulating film 45a, the via insulating film 46, the trench insulating film 47, and the hard mask 48 may be formed in the same chamber by using one kind of monomer through changing the film-forming condition of plasma polymerization. Alternatively, the second insulating film 45a, the via insulating film 46, the trench insulating film 47, and the hard mask 48 may be formed by changing the ratio of two kinds or more monomers.

A raw material having a straight-chain organic silica structure shown in Expression 5 was used to form the barrier insulating film 45a.

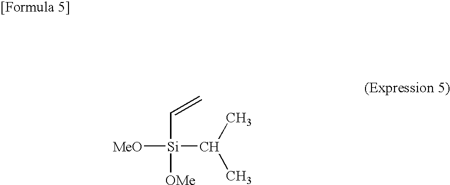

The raw material monomer within the raw material tank 302 of the VU1 side shown in FIG. 35 is pressured out by He gas supplied from the pressuring gas supplying device 306, and it is introduced into the vaporizing part 312 along with the He gas supplied from the carrier gas supplying tank 306. The raw material monomer introduced into the vaporizing part 312 is preferable to be between 0.1 g/min and 10 g/min, both inclusive, and more preferable to be 2 g/min or less. The raw material monomer is vaporized in the vaporizing part 312, and it is introduced into the reaction chamber 210 along with the He gas supplied from the carrier gas supplying tank 306. The carrier gas supplying amount is preferable to be between 50 sccm and 5000 sccm, both inclusive, and more preferable to be 2000 sccm or less. In the reaction chamber 210, the film is formed with a plasma polymerization reaction by a high frequency of 13.56 MHz that is supplied from the high-frequency power source 240. The power supplied from the high-frequency power source 240 is preferable to be 2000 W or less, and more preferable to be 1000 W or less. Further, the pressure in the reaction chamber 210 when forming the film is preferable to be in a range of 133-1333 Pa.

The via insulating film 45 was formed by using a raw material having a cyclic organic silica structure shown in Expression 3 and a raw material having a straight-chain organic silica structure shown in Expression 5.

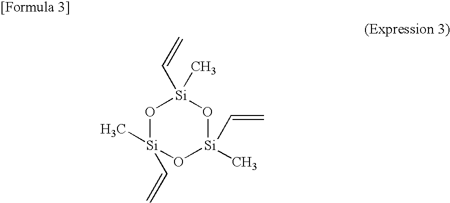

The raw material monomer shown in Expression 5 within the raw material tank 302 of the VU1 side shown in FIG. 35 is pressured out by the He gas supplied from the pressuring gas supplying device 306, and it is introduced into the vaporizing part 312 along with the He gas supplied from the carrier gas supplying tank 306. The raw material monomer introduced into the vaporizing part 312 is preferable to be between 0.1 g/min and 10 g/min, both inclusive, and more preferable to be 2 g/min or less. The raw material monomer is vaporized in the vaporizing part 312, and it is introduced into the mixer 340 along with the He gas supplied from the carrier gas supplying tank 306. The carrier gas supplying amount is preferable to be between 50 sccm and 5000 sccm, both inclusive, and more preferable to be 2000 sccm or less. In the meantime, the raw material monomer shown in Expression 3 within the raw material tank 302 of the VU2 side is pressured out by the He gas supplied from the pressuring gas supplying device 306, and it is introduced into the vaporizing part 312 along with the He gas supplied from the carrier gas supplying tank 306. The raw material monomer introduced into the vaporizing part 312 is preferable to be between 0.1 g/min and 10 g/min, both inclusive, and more preferable to be 2 g/min or less. The raw material monomer is vaporized in the vaporizing part 312, and it is introduced into the mixer 340 along with the He gas supplied from the carrier gas supplying tank 306. The mixed ratio of the raw material monomer shown in Expression 5 and the raw material monomer shown in Expression 3 introduced into the mixer 340 is preferable to be 1:9-9:1. The raw material monomers vaporized after going through the mixer 340 and the carrier gas are introduced into the reaction chamber 210. In the reaction chamber 210, the film is formed with a plasma polymerization reaction by a high frequency of 13.56 MHz that is supplied from the high-frequency power source 240. The power supplied from the high-frequency power source 240 is preferable to be 2000 W or less, and more preferable to be 1000 W or less. Further, the pressure in the reaction chamber 210 when forming the film is preferable to be in a range of 133-1333 Pa.

A raw material having a straight-chain organic silica structure shown in Expression 3 was used to form the trench insulating film 47. The raw material monomer within the raw material tank 302 of the VU2 side shown in FIG. 35 is pressured out by the He gas supplied from the pressuring gas supplying device 306, and it is introduced into the vaporizing part 312 along with the He gas supplied from the carrier gas supplying tank 306. The raw material monomer introduced into the vaporizing part 312 is preferable to be between 0.1 g/min and 10 g/min, both inclusive, and more preferable to be 2 g/min or less. The raw material monomer is vaporized in the vaporizing part 312, and it is introduced into the reaction chamber 210 along with the He gas supplied from the carrier gas supplying tank 306. The carrier gas supplying amount is preferable to be between 50 sccm and 5000 sccm, both inclusive, and more preferable to be 2000 sccm or less. In the reaction chamber 210, the film is formed with a plasma polymerization reaction by a high frequency of 13.56 MHz that is supplied from the high-frequency power source 240. The power supplied from the high-frequency power source 240 is preferable to be 2000 W or less, and more preferable to be 1000 W or less. Further, the pressure in the reaction chamber 210 when forming the film is preferable to be in a range of 133-1333 Pa.

A raw material having a straight-chain organic silica structure shown in Expression 5 was used to form the hard mask 48. The raw material monomer within the raw material tank 302 of the VU1 side shown in FIG. 35 is pressured out by the He gas supplied from the pressuring gas supplying device 306, and it is introduced into the vaporizing part 312 along with the He gas supplied from the carrier gas supplying tank 306. The raw material monomer introduced into the vaporizing part 312 is preferable to be between 0.1 g/min and 10 g/min, both inclusive, and more preferable to be 2 g/min or less. The raw material monomer is vaporized in the vaporizing part 312, and it is introduced into the reaction chamber 210 along with the He gas supplied from the carrier gas supplying tank 306. The carrier gas supplying amount is preferable to be between 50 sccm and 5000 sccm, both inclusive, and more preferable to be 2000 sccm or less. In the reaction chamber 210, the film is formed with a plasma polymerization reaction by a high frequency of 13.56 MHz that is supplied from the high-frequency power source 240. The power supplied from the high-frequency power source 240 is preferable to be 2000 W or less, and more preferable to be 1000 W or less. Further, the pressure in the reaction chamber 210 when forming the film is preferable to be in a range of 133-1333 Pa.

The films may be formed by continuously executing two consecutive steps or more for the barrier insulating film 45a, the via insulating film 46, the trench insulating film 47, and the hard mask 48 within the same chamber. Alternatively, those films may be formed by using different film-forming devices.

FIG. 27 shows the result of depth direction analysis conducted on elements distribution by using X-ray photoelectron spectroscopy. Through continuously forming the barrier insulating film 45a, the via insulating film 46, the trench insulating film 47, and the hard mask 48 within the same chamber in this manner, the number of devices to be provided can be reduced and the throughput is expected to improve. Therefore, it is possible to cut the cost.

The semiconductor device configured with a double-layer Cu wiring (copper-containing wiring) having the upper layer and the lower layer was fabricated through a procedure shown in FIG. 16 in a stacked insulating film structure formed in the manner described above.

### Comparative Example 1

As Comparative Example 1, a semiconductor device configured with a double-layer copper-containing wiring having an upper layer and a lower layer was fabricated as in FIG. 36 by using a typical SiCN film (k=4.9) as the barrier insulating film. An SiOCH film with a relative dielectric constant of 2.8 was used as the via insulating film, and an SiOCH film with a relative dielectric constant of 3.1 was used as the hard mask. As the trench insulating film, a film with a relative dielectric constant of 2.45, which was made with a raw material having the same cyclic organic silica structure as that of the trench insulating film of the fifth embodiment described above, was used. Each of the films was formed in the same thickness of the respective films of the fifth embodiment described above, and each film was formed in a different chamber from each other.

### Comparative Example 2

As Comparative Example 2, a semiconductor device configured with a double-layer copper-containing wiring having an upper layer and a lower layer was fabricated as in FIG. 36 by using a typical SiCN film (k=4.9) as the barrier insulating film. The films other than the barrier insulating film, i.e., the via insulating film (k=2.5), the trench insulating film (k=2.45), and the hard mask (k=3.1), were formed continuously in a same chamber through the same method, in the same thicknesses, and by using the same materials as those of the fifth embodiment described above.

A table shown in FIG. 36 shows the film characteristics of the insulating films used in the fifth embodiment, Comparative Example 1, and Comparative Example 2.

FIG. 28 is an illustration showing the adhesive strength of the interface between the barrier insulating film and the via insulating film with respect to the effective dielectric constant of the via insulating film in the wiring structure of the fourth embodiment. The reference expressions in this illustration correspond to those shown in the table of FIG. 36. It was verified that the structure shown in the fifth embodiment exhibited a still higher adhesive strength compared to the adhesiveness in the interface of the via (SiOCH) and the barrier (SiCN) of Comparative Example 1, even though the effective dielectric constant of the via is low. Further, it was verified that the adhesiveness in the interface can be improved by interposing a film that is applied as the barrier insulating film in this case, even when the via or the trench insulating film was formed on SiCN that is a typical barrier. As described, the barrier insulating film used herein has an effect of improving the adhesiveness in addition to having the Cu diffusion preventing effect.

FIG. 29 shows electron microscopic pictures of sections of the wiring structures fabricated in the fifth embodiment and Comparative Example 1, processed by applying dilute fluoric acid after dry-etching via and groove. With the structure using the via insulating film of Comparative Example 1, a state where the via insulating film in the periphery of the via hole is etched by the dilute fluoric acid treatment can be observed. This is because C in the via insulating film is released and turned into SiO by an influence of oxygen plasma (so-called low-k ashing damage), at to the time of resist ashing using the oxygen plasma during the processing. With the ashing damage, there are concerns regarding an increase in the effective dielectric constant and an influence to the reliability. In the meantime, there is no encroachment in the insulating film observed by the ashing damage with the structure of the fifth embodiment. The fifth embodiment uses a C-rich film for the via insulating film (table shown in FIG. 36), so that it is considered to have a high resistant property for the oxygen plasma.

FIG. 30 is a graph showing a distribution of via resistance (yield) of 80 nm^{φ} via obtained from 75 mega via chain patterns fabricated according to the fifth embodiment, Comparative Example 1, and Comparative Example 2. The via resistance of about 2Q was obtained and 90% or more yield was achieved with all the structures.

FIG. 31 is a graph which compares capacitances between different layers in the double-layer wiring structures fabricated according to the fifth embodiment, Comparative Example 1, and Comparative Example 2. With the wiring structure of the fifth embodiment, reduction of 11.7% in the capacitance between the different layers was observed with respect to Comparative Example 1, while reduction of 6.3% was observed with respect to Comparative Example 2. This is considered because of the effect of lowering the dielectric constant of the via insulating film (from k=2.8 to k=2.5) and the dielectric constant of the barrier insulating film (from k=4.9 to k=3.1), and the effect of employing the film with high ashing damage resistant property for the via insulating film.

FIG. 32 is an illustration showing current-voltage characteristics between the neighboring wirings (100 nm space) of the wiring structures fabricated according to the fifth embodiment, Comparative Example 1, and Comparative Example 2. In those structures, there is no notable different regarding the I-V characteristics, and the dielectric breakdown field is about 6 MV/cm. Therefore, it was verified that a sufficient insulating characteristic was achieved.

FIG. 33 is a graph showing the result of a test conducted regarding the electro migration resistant property of 80 nm^{φ} via in the double-layer wiring structures fabricated according to the fifth embodiment, Comparative Example 1, and Comparative Example 2. Specifically, the test was conducted under a condition with a temperature at 350 degrees C. and 6 MA/cm² current density. The graph shows an accumulated failure probability distribution while having the time at which the resistance increase rate exceeds 3% as the failure time. Compared to the samples of Comparative Examples, it was verified that the sample of the embodiment had a long life and had a smaller variation in the failure time. It was also verified that the sample of the embodiment has the electro migration resistant property of 5 times or more compared to the life (T 0.1) where the accumulated failure probability became 0.1%.

While the present invention has been described by referring to the embodiments (and examples), the present invention is not limited only to those embodiments (and examples) described above. Various kinds of modifications that occur to those skilled in the art can be applied to the structures and details of the present invention within the scope of the present invention.

This Application claims the Priority right based on JP 2006-345433 filed on Dec. 22, 2006 and JP 2007-186482 filed on Jul. 18, 2007, and the disclosures thereof are hereby incorporated by reference in the entirety.

### BRIEF DESCRIPTION OF THE DRAWINGS

FIG. 1 is a sectional view showing a semiconductor device according to a first embodiment of the present invention;

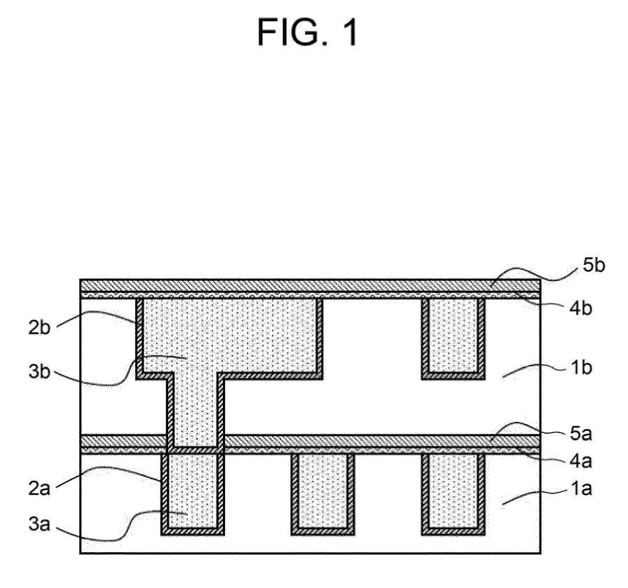

FIG. 2 shows sectional views which illustrate a manufacturing method of the semiconductor device according to the first embodiment of the present invention in order of manufacturing steps;

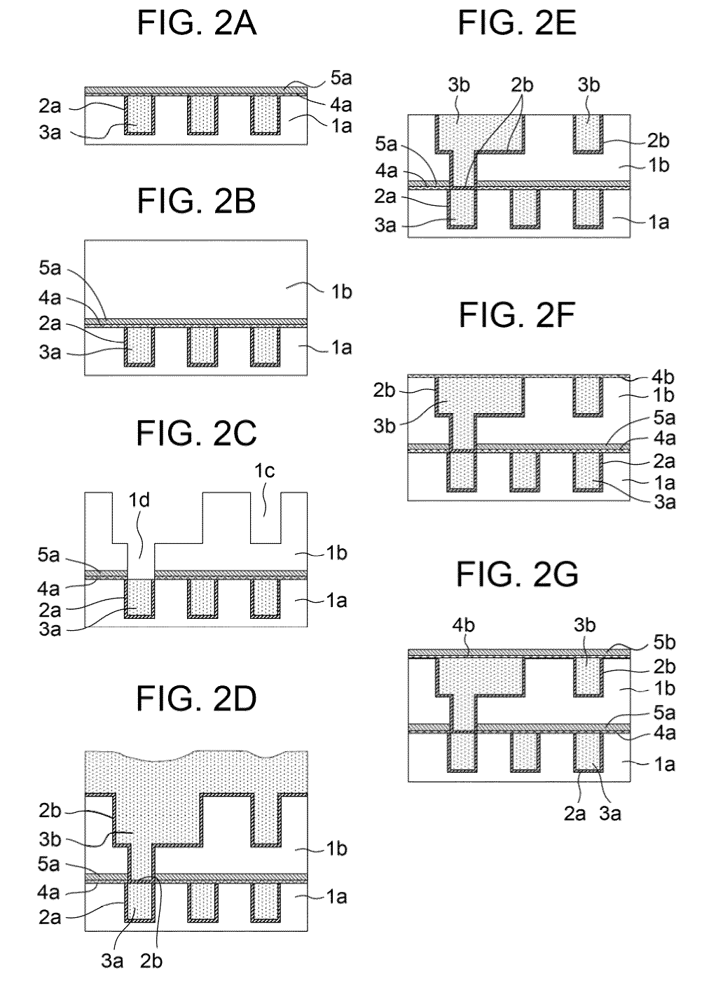

FIG. 3 is a schematic view of a film-forming device according to the embodiment of the present invention, which forms an outer-layer barrier insulating film made with an organic silica of a low dielectric constant;

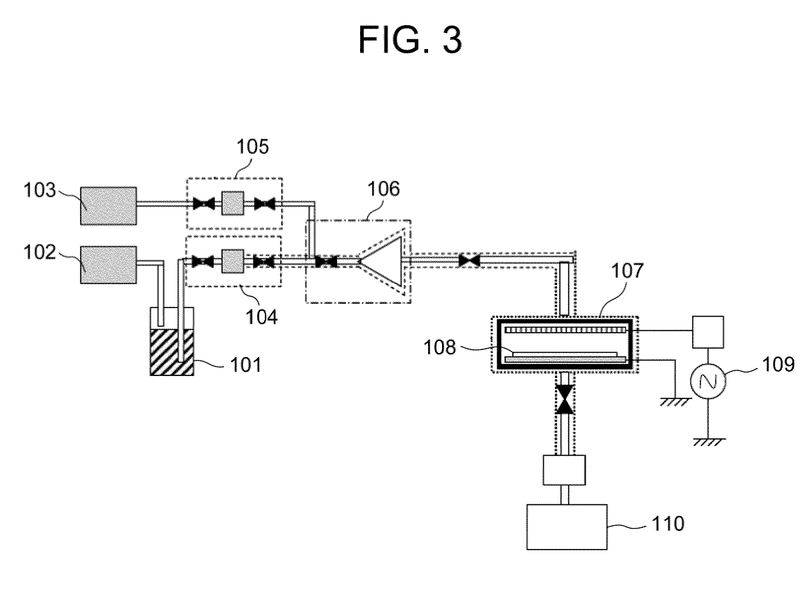

FIG. 4 is a graph showing a result of Raman spectral analysis conducted on the outer-layer barrier insulating film made with the organic silica of the low dielectric constant according to the embodiment of the present invention;

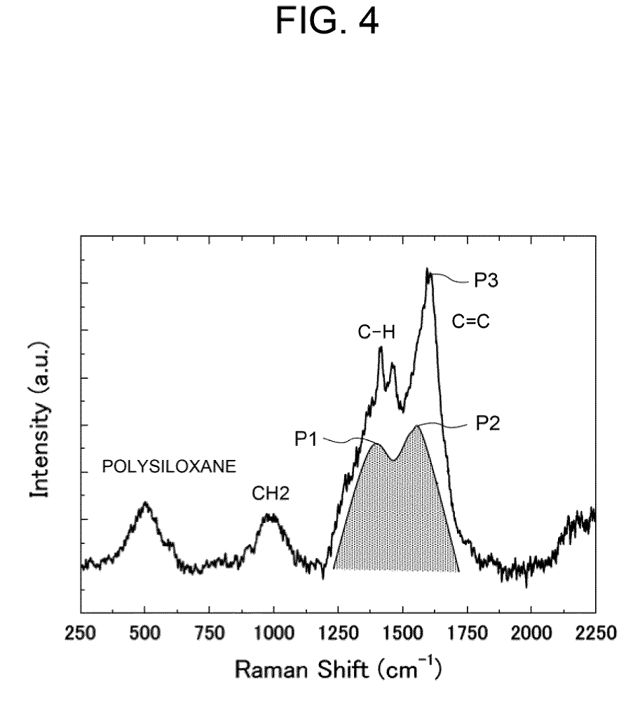

FIG. 5 shows graphs for describing an effect (Cu diffusion resistant property) of the embodiment of the present invention;

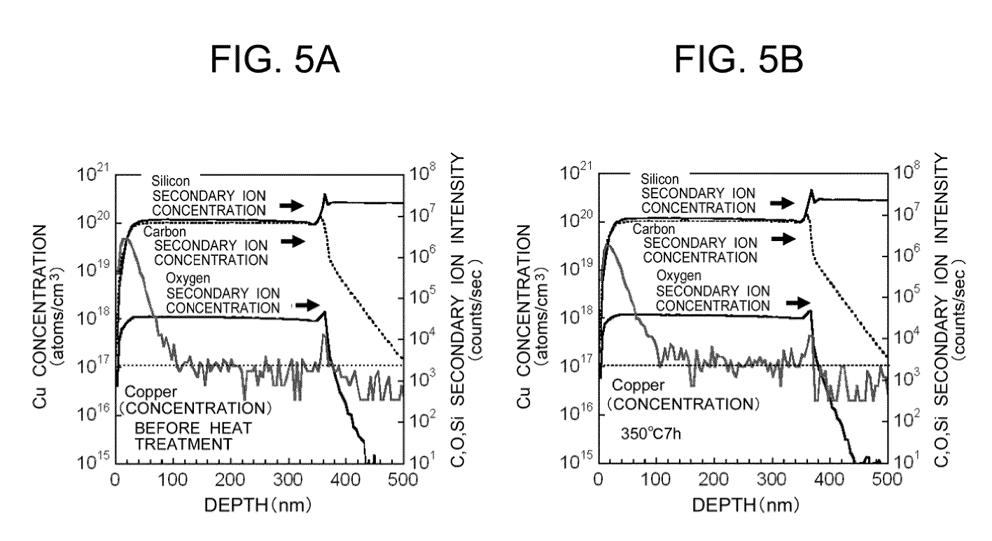

FIG. 6 shows a graph for describing an effect (film strength) of the embodiment of the present invention;

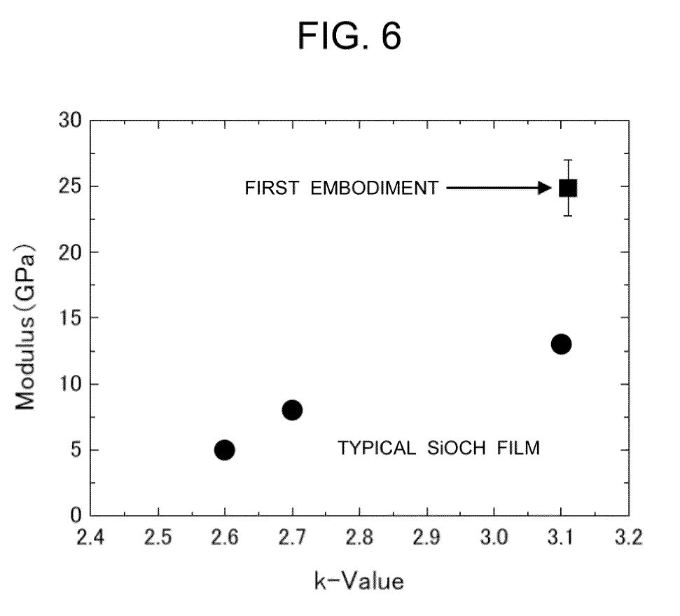

FIG. 7 shows a graph for describing an effect (film adhesive strength) of the embodiment of the present invention;

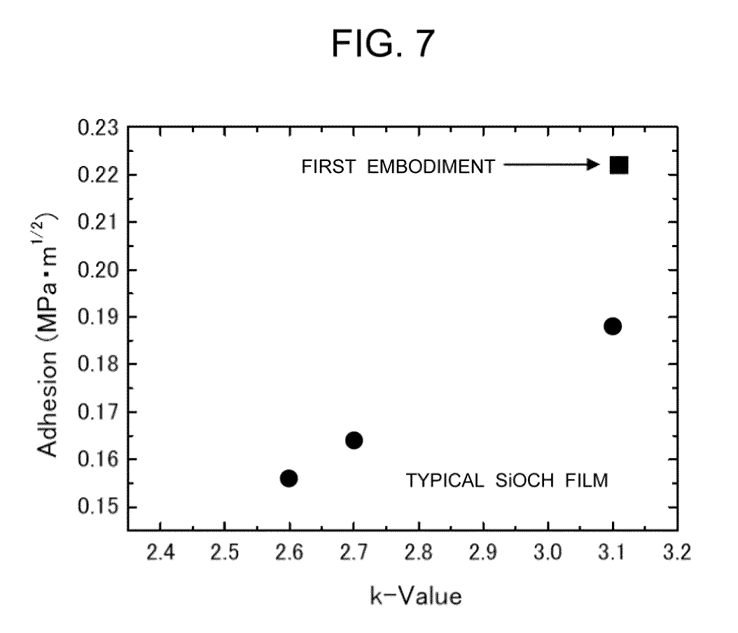

FIG. 8 shows sectional views which illustrate a manufacturing method of a semiconductor device according to a second embodiment of the present invention in order of manufacturing steps;

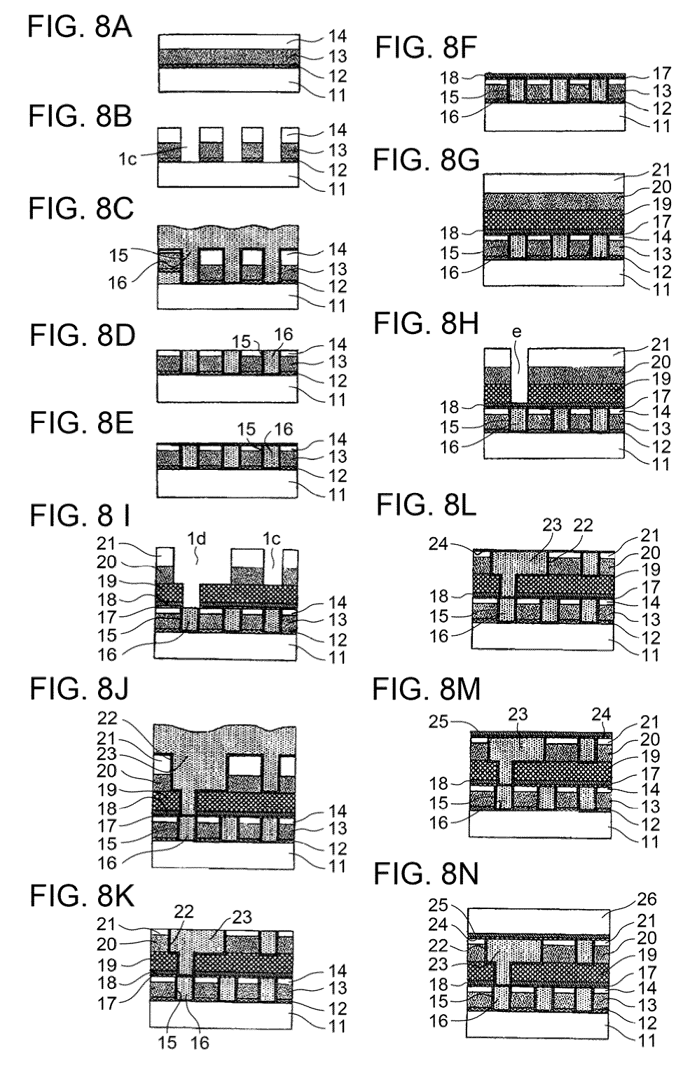

FIG. 9 shows a graph for describing an effect (effective dielectric constant) of the second embodiment of the present invention;

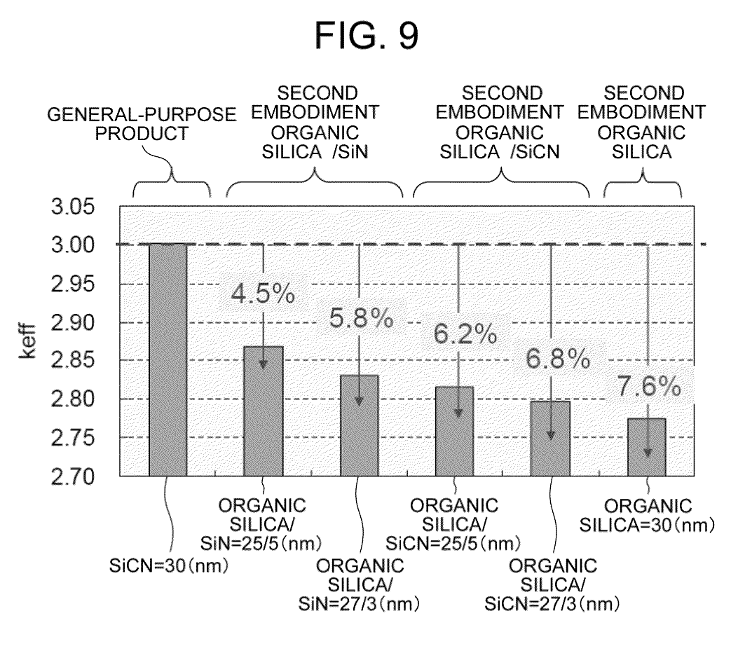

FIG. 10 is a sectional view showing a semiconductor device according to a third embodiment of the present invention;

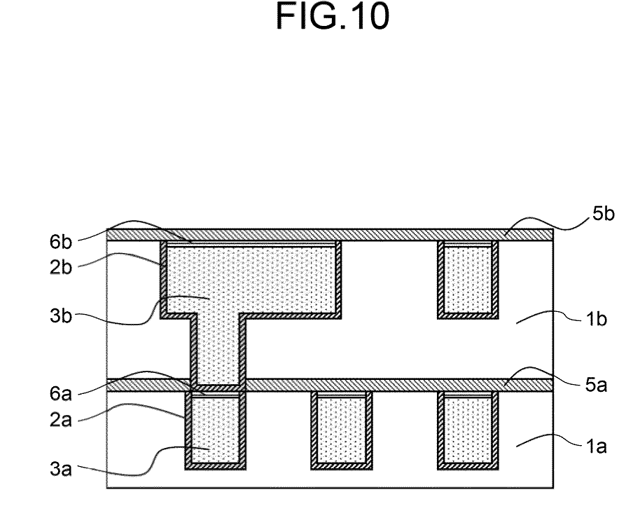

FIG. 11 is a sectional view showing the semiconductor device according to the third embodiment of the present invention;

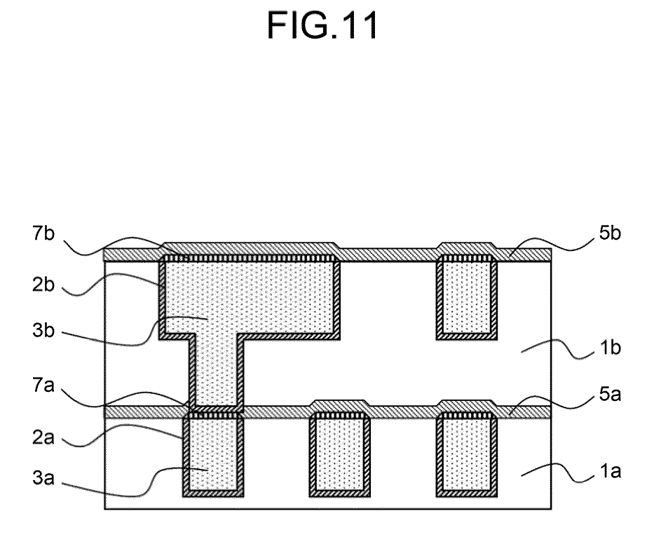

FIG. 12 shows sectional views which illustrate a manufacturing method of the semiconductor device according to the third embodiment of the present invention;

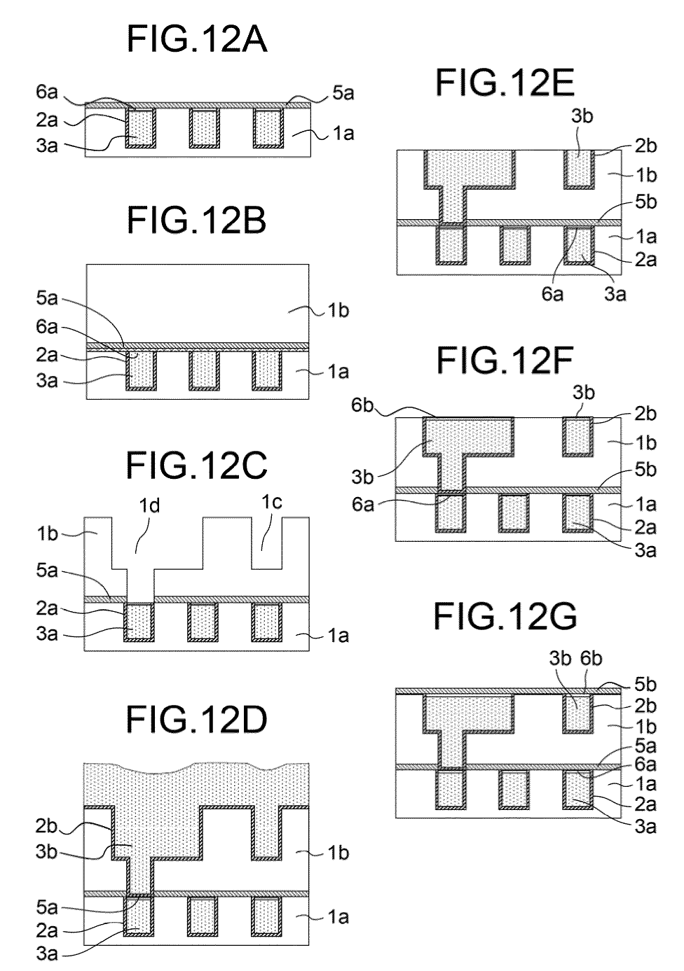

FIG. 13 shows sectional views which illustrate the manufacturing method of the semiconductor device according to the third embodiment of the present invention;

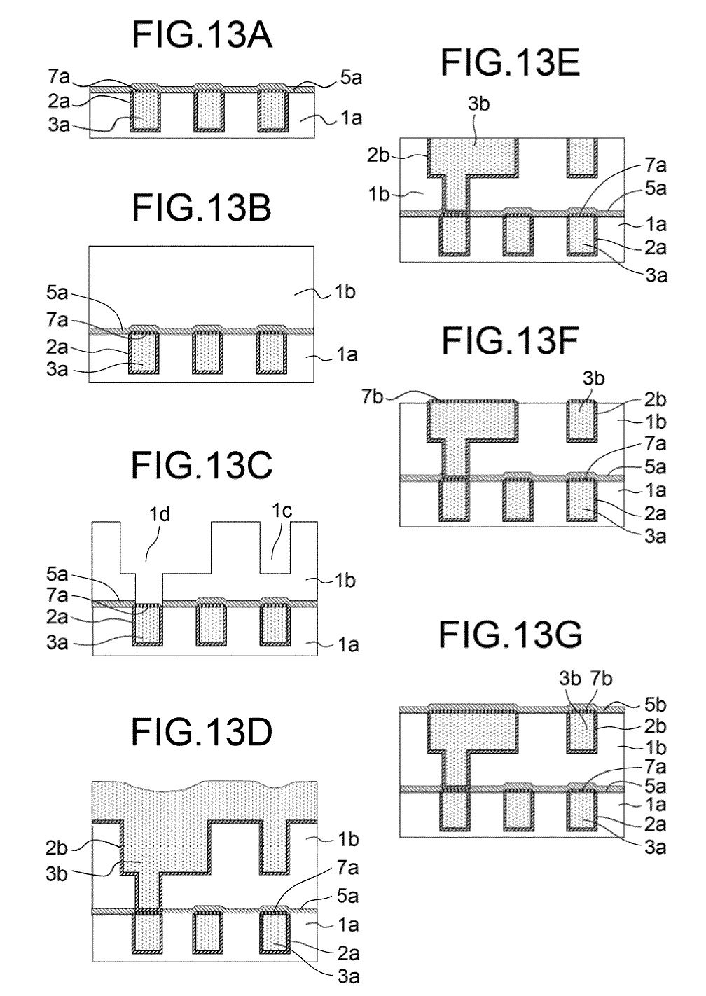

FIG. 14 is a sectional view showing a semiconductor device according to a fourth embodiment of the present invention;

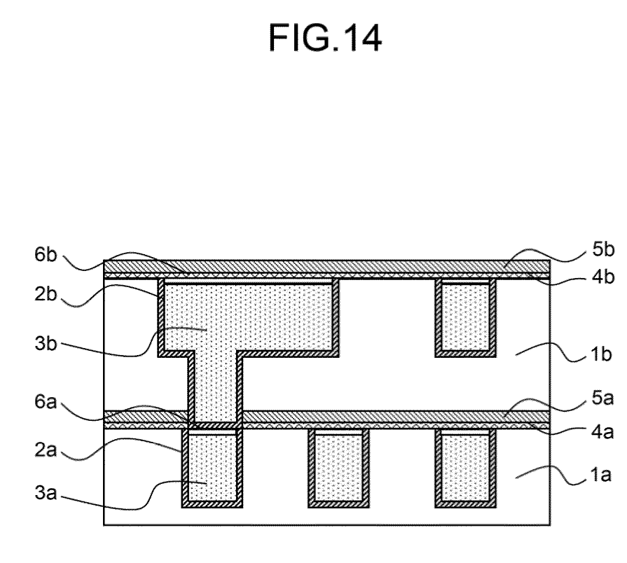

FIG. 15 is a sectional view showing the semiconductor device according to the fourth embodiment of the present invention;

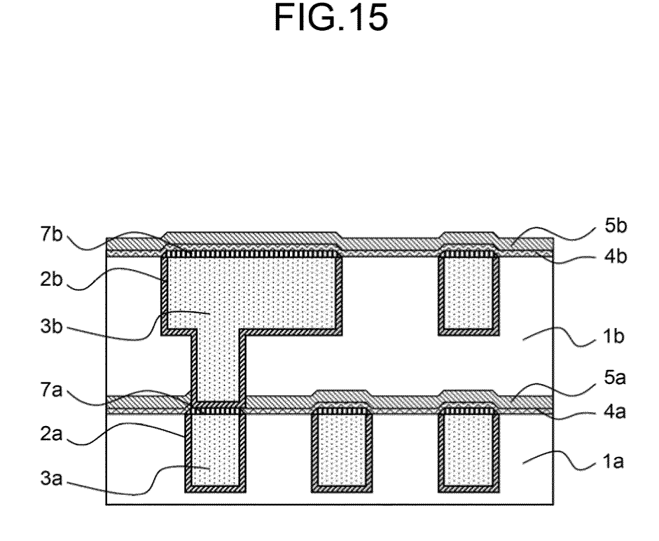

FIG. 16 shows sectional views which illustrate a manufacturing method of the semiconductor device according to the fourth embodiment of the present invention;

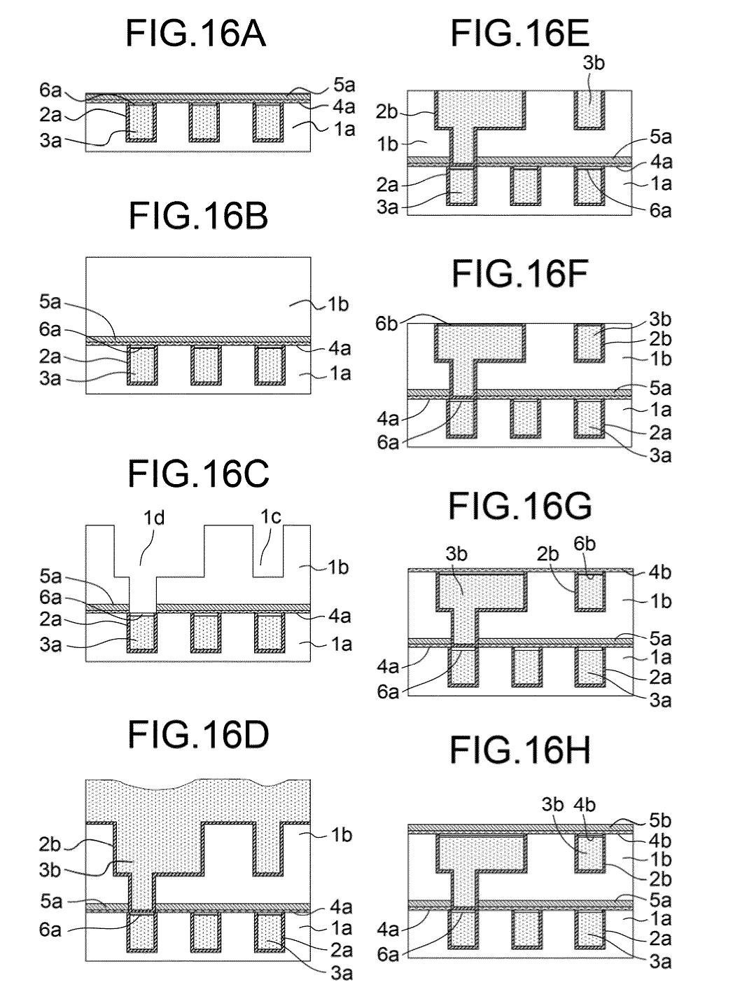

FIG. 17 shows sectional views which illustrate a manufacturing method of the semiconductor device according to the fourth embodiment of the present invention;

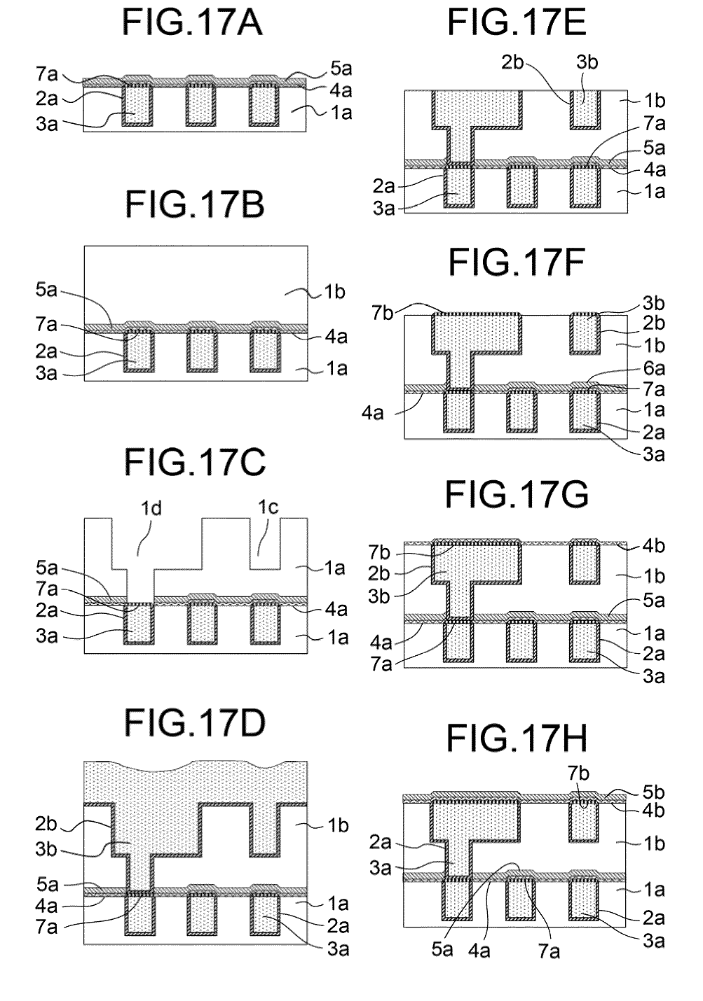

FIG. 18 is a sectional view showing a semiconductor device according to a fifth embodiment of the present invention;

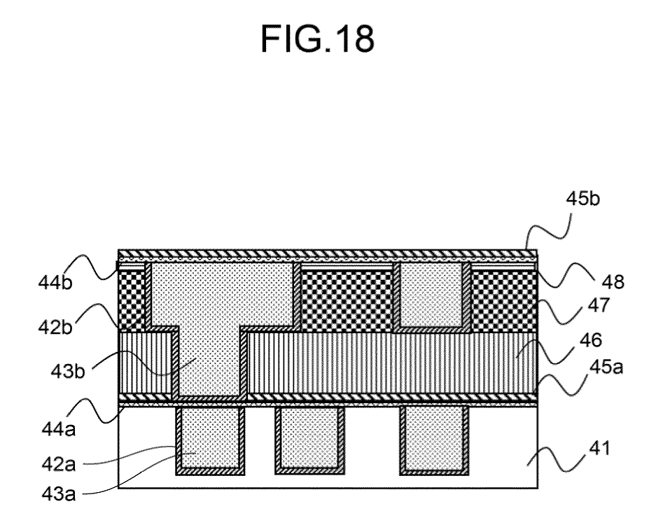

FIG. 19 shows sectional views which illustrate a manufacturing method of the semiconductor device according to the fifth embodiment of the present invention;

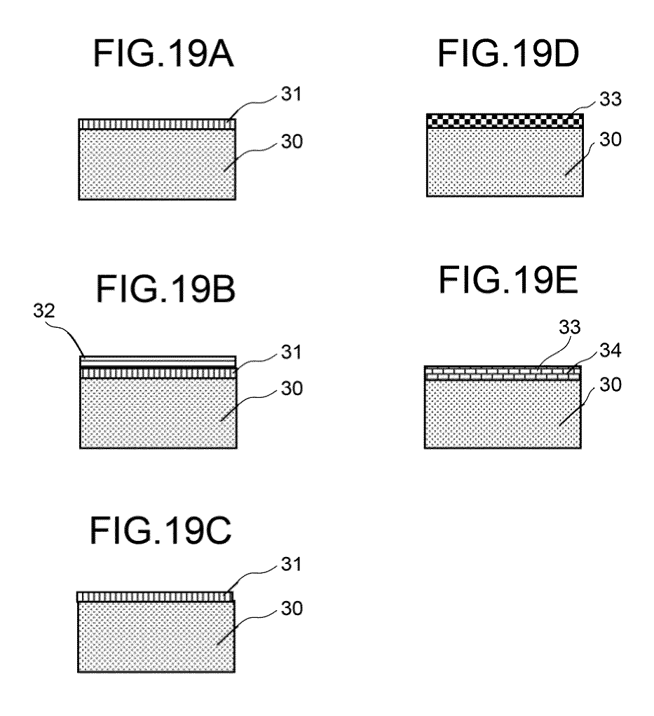

FIG. 20 shows sectional views which illustrate a manufacturing method of the semiconductor device according to the fifth embodiment of the present invention;

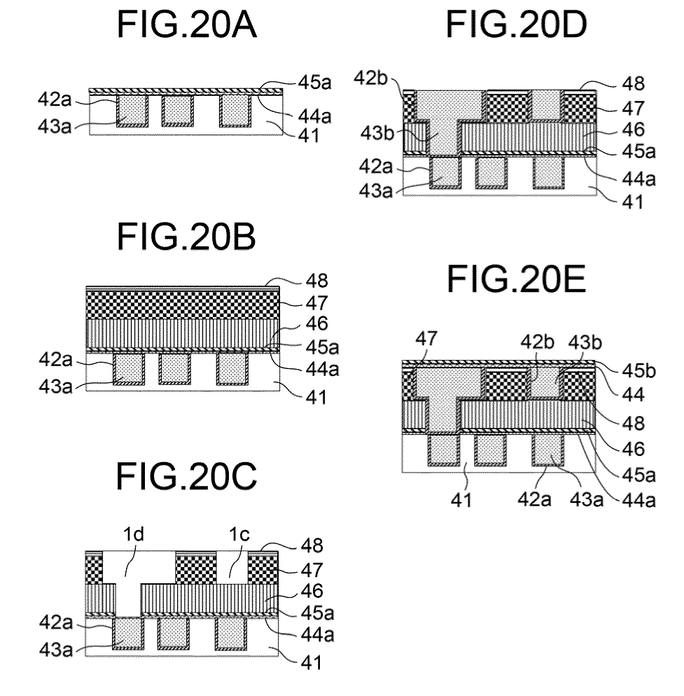

FIG. 21 shows thermal desorption analysis spectrum graphs regarding remaining amounts of anticorrosive agent before and after applying heat treatment in an N₂ atmosphere according to the fifth embodiment of the present invention;

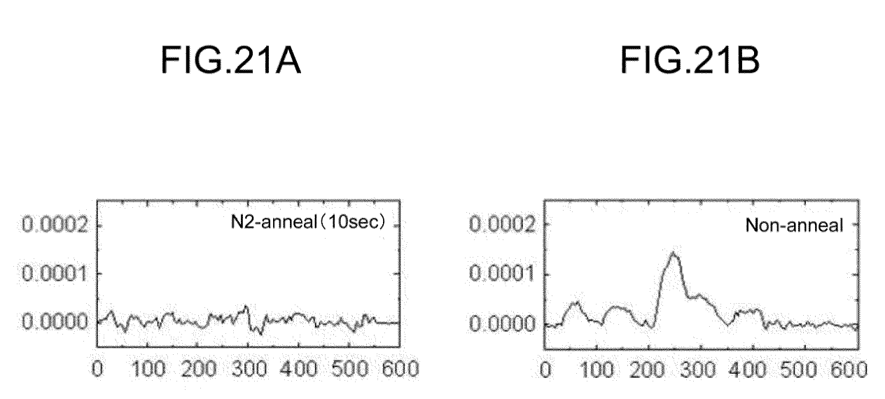

FIG. 22 is a graph showing the remaining amounts of the anticorrosive agent with respect to heat treatment time according to the fifth embodiment of the present invention;

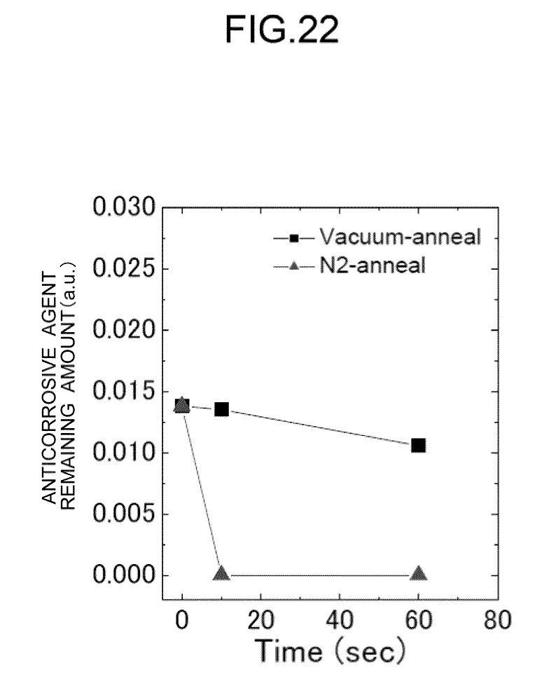

FIG. 23 is a graph showing changes in sheet resistant with respect to SiH₄ flow amounts according to the fifth embodiment of the present invention;

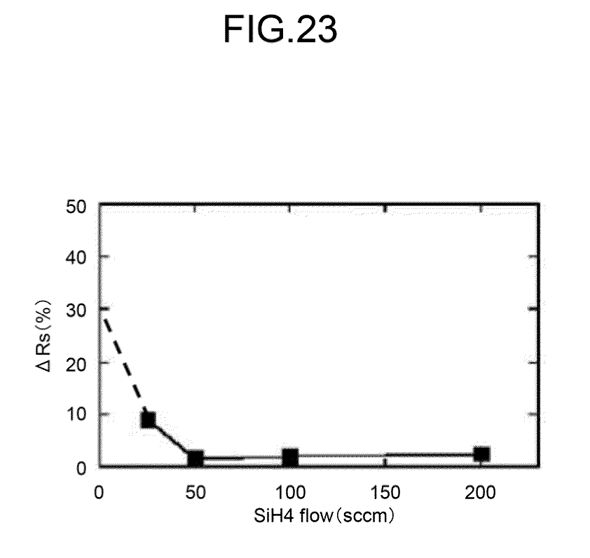

FIG. 24 is a graph showing oxygen existing ratios at a depth of 5 nm from the surface with respect to SiH₄ flow amounts according to the fifth embodiment of the present invention;

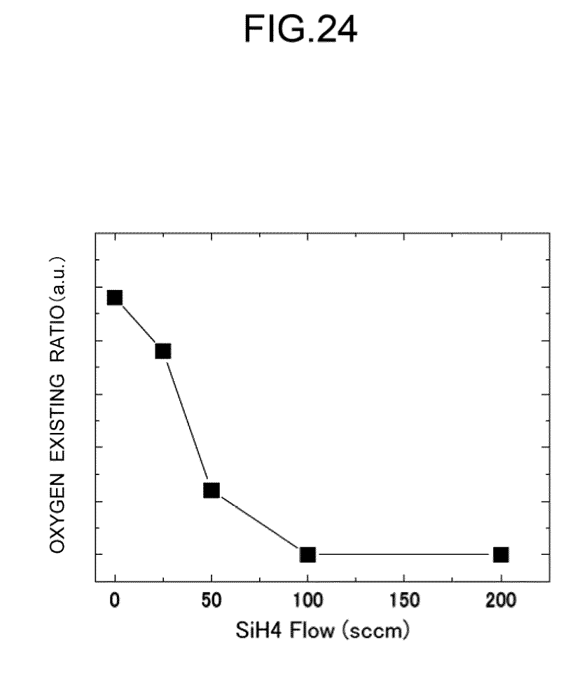

FIG. 25 is a graph showing a Cu diffusion barrier characteristic of a barrier insulating film of a wiring structure according to the fifth embodiment of the present invention;

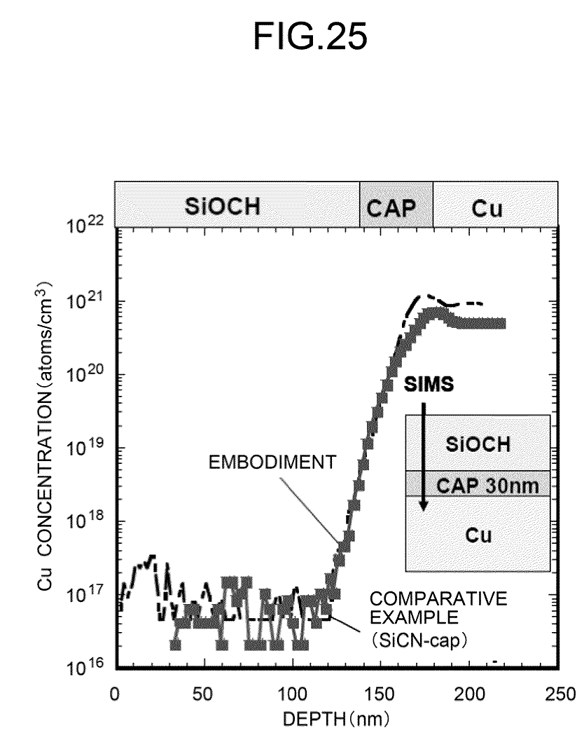

FIG. 26 is a graph showing a current-voltage characteristic of the barrier insulating film of the wiring structure according to the fifth embodiment of the present invention;

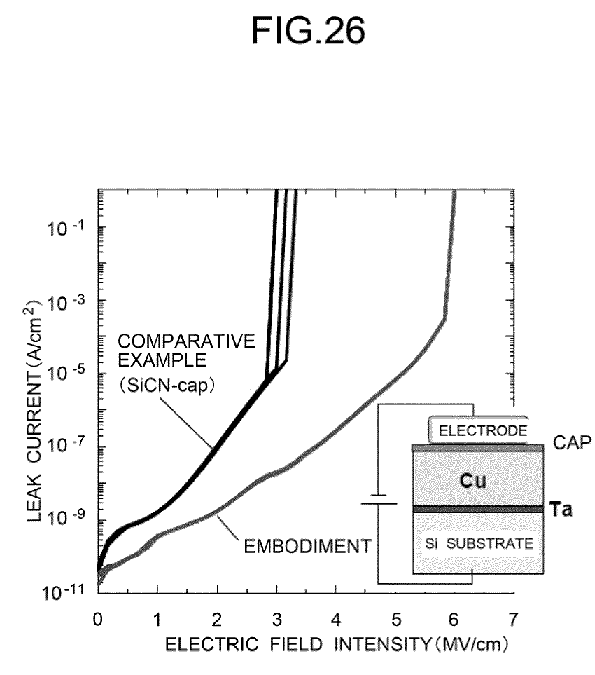

FIG. 27 is a graph showing an example of a distribution of elements in the barrier insulating film of the wiring structure according to the fifth embodiment of the present invention;

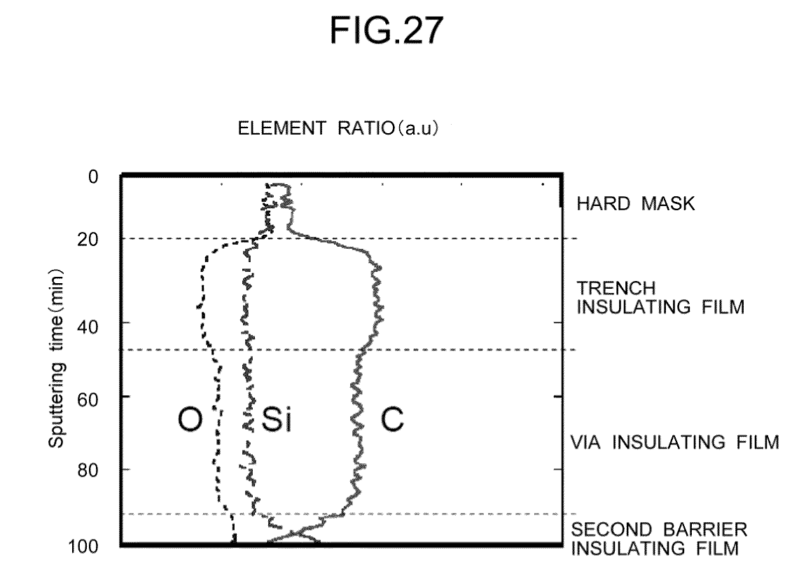

FIG. 28 is an illustration showing adhesive strength of the interface between the barrier insulating film and the via insulating film in the wiring structure according to the fifth embodiment of the present invention;

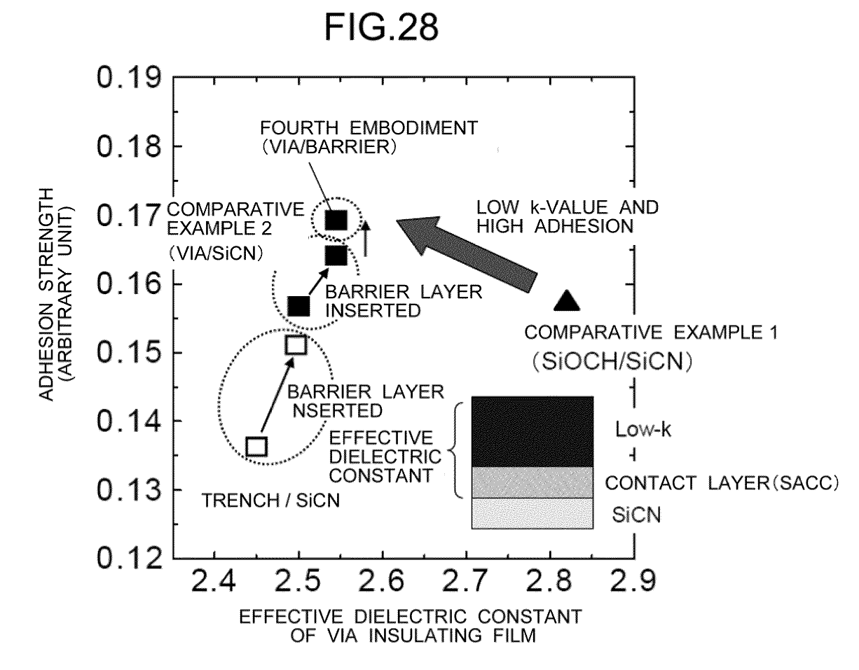

FIG. 29 shows electron microscopic pictures of sections of the wiring structures fabricated in the fifth embodiment and Comparative Example 1, processed by applying dilute fluoric acid after dry-etching via and groove;

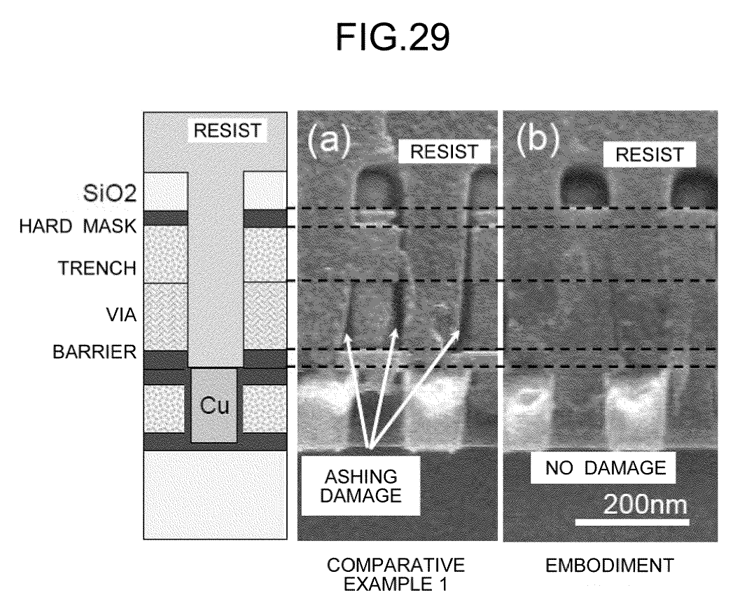

FIG. 30 is a graph showing a distribution of via resistance (yield) of 80 nm^{φ} via obtained from 75 mega via chain patterns fabricated according to the fifth embodiment, Comparative Example 1, and Comparative Example 2

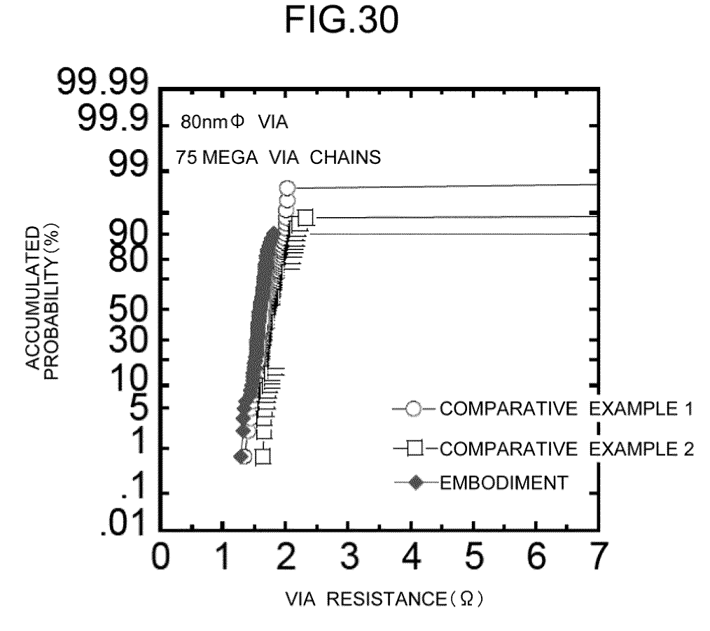

FIG. 31 is a graph showing a distribution of capacitances between different layers in the double-layer wiring structures fabricated according to the fifth embodiment, Comparative Example 1, and Comparative Example 2;

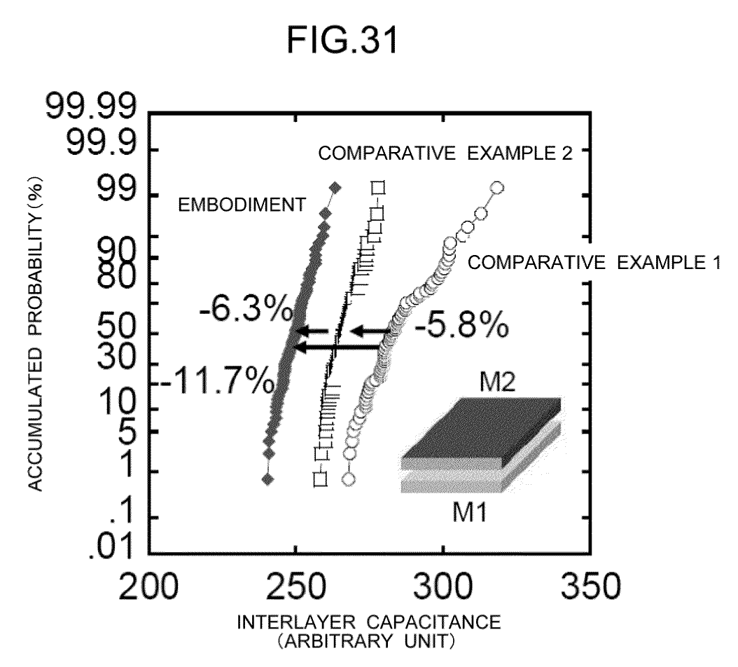

FIG. 32 is an illustration showing current-voltage characteristics between the neighboring wirings (100 nm space) of the wiring structures fabricated according to the fifth embodiment, Comparative Example 1, and Comparative Example 2;

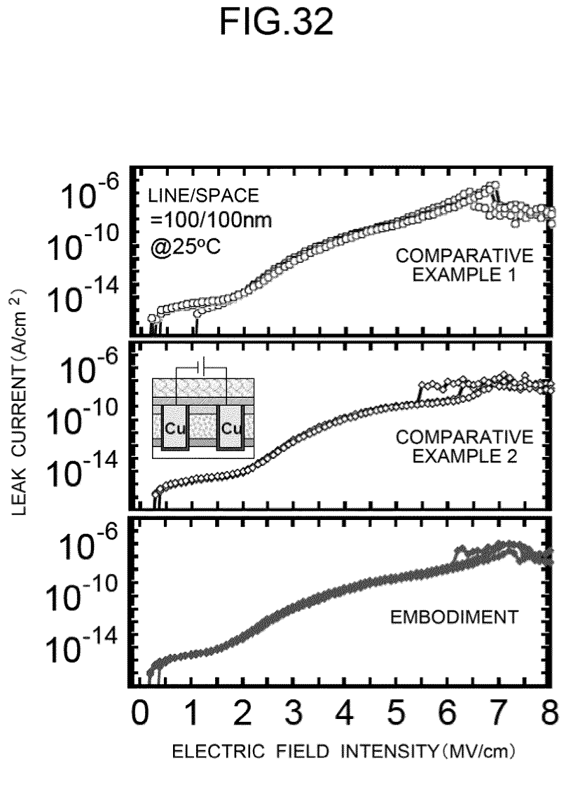

FIG. 33 is a graph showing a distribution of failure time due to the electro migration of 80 nm^{φ} via in the wiring structures fabricated according to the fifth embodiment, Comparative Example 1, and Comparative Example 2;

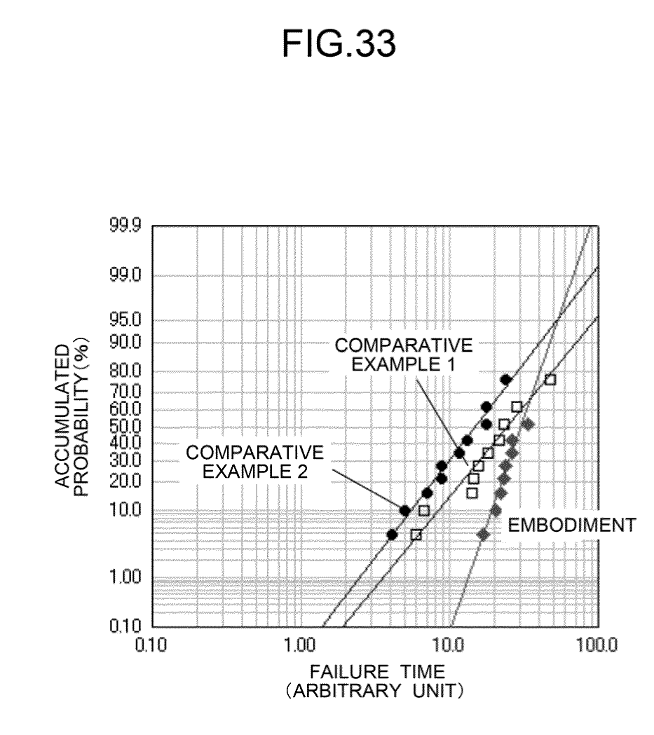

FIG. 34 is a schematic view of a film-forming device according to the fifth embodiment of the present invention;

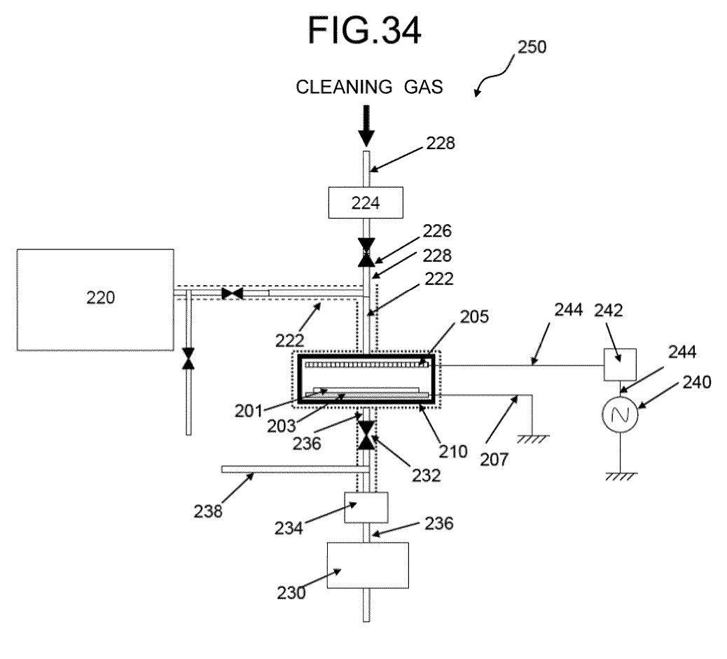

FIG. 35 is a schematic view of the film-forming device according to the fifth embodiment of the present invention;

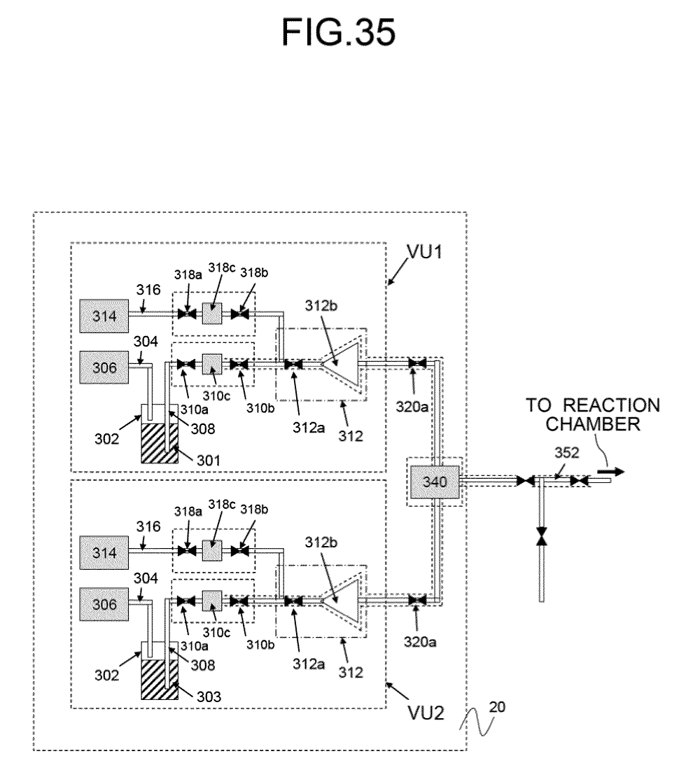

FIG. 36 is a table showing film characteristics of the insulating films used in the fifth embodiment, Comparative Example 1, and Comparative Example 2; and

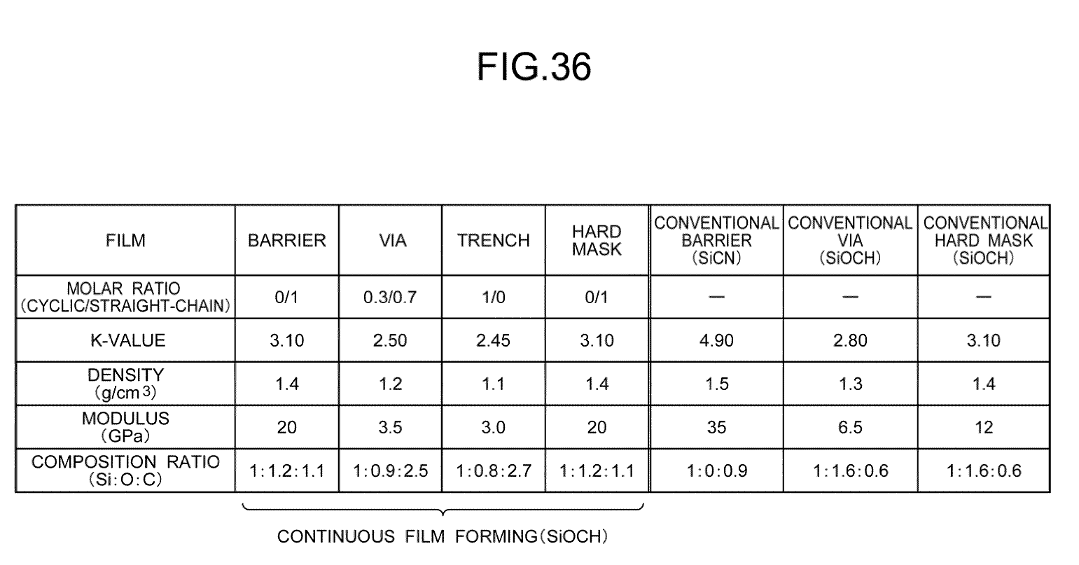

FIG. 37 shows sectional views which illustrate manufacturing steps of a semiconductor device according to a related art.

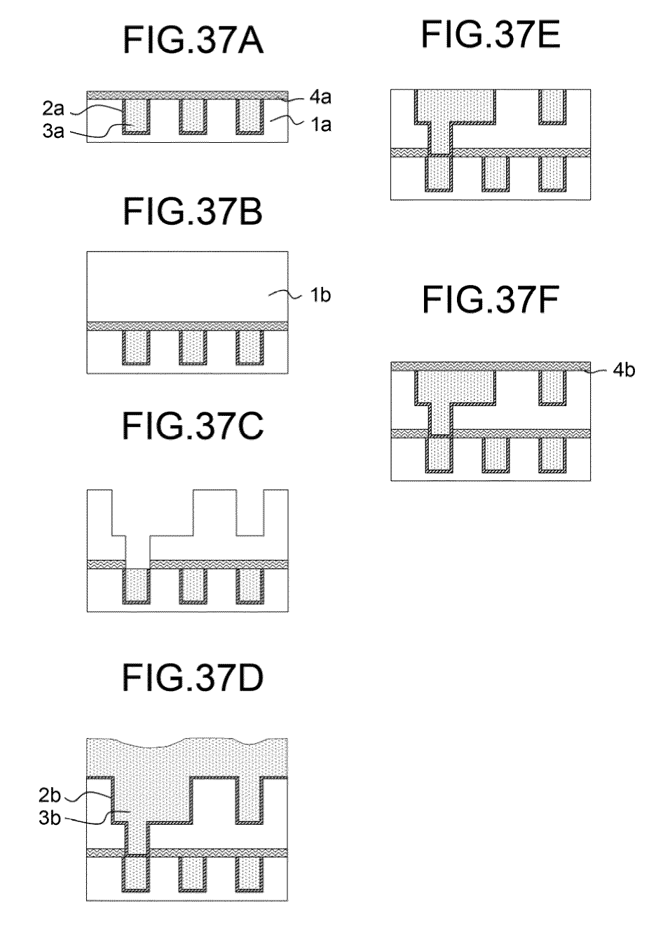

### REFERENCE NUMERALS

1a Insulating film
1b Insulating film
2a Barrier metal
2b Barrier metal
3a Cu or Cu alloy
3b Cu or Cu alloy
4a Barrier insulating film
4b Barrier insulating film
5a Barrier insulating film made with organic silica (configured with SiOCH)
5b Barrier insulating film made with organic silica (configured with SiOCH)
6a Cu surface modified layer
6b Cu surface modified layer
7a Metal cap layer
7b Metal cap layer
11 Insulating film
12 Etching stop film
13 Inter-wiring insulating film
24 Barrier insulating film (lower layer)
25 Barrier insulating film (upper layer)
26 Cover insulating film
101 Reserver
102 Raw material pressuring-out part
103 Carrier gas supplying part
104 Liquid gas massflow
105 Gas massflow
106 Vaporizer
107 Reactor
108 RF power source
109 Substrate
110 Exhaust pump
201 Film-forming member
203 Substrate heating part
205 Shower head
207 Earth line
210 Reaction chamber
220 Gas supplying part
222 Gas supplying pipe
224 Flow amount controller
226 Valve
228 Cleaning gas supplying pipe
230 Vacuum pump
232 Valve
234 Cooling trap
236 Gas exhaust pipe
238 Drain pipe
240 High-frequency power source
242 Matching box
244 High-frequency cable
250 Plasma CVD device
301, 303 Organic siloxane raw material
302 Raw material tank
304 Pressuring gas supplying pipe
306 Pressuring gas supplying device
308 Raw material transporting pipe
310 Liquid flow amount controlling part
310a, 310b Valve
310c Liquid flow amount controller
312 Vaporizing part
312a Valve
312b Vaporizer
314 Carrier gas supplying tank
316 Pipe
318 Gas flow amount controlling part
318a, 318b Valve
318c Gas flow amount controller
320 Gas exhaust pipe
340 Mix
352 Gas exhaust pipe

1. A semiconductor device having a copper-containing wiring, wherein:
the copper-containing wiring is covered by a barrier insulating film; and
the barrier insulating film contains a component of organic silica which contains unsaturated hydrocarbon and amorphous carbon.

2. The semiconductor device as claimed in claim 1, wherein:
the barrier insulating film has a single-layer structure; and
the barrier insulating film is formed with the organic silica containing the unsaturated hydrocarbon and the amorphous carbon.

3. The semiconductor device as claimed in claim 1, wherein:
the barrier insulating film has a double-layer structure configured with an inner barrier insulating film which covers a surface of the copper-containing wiring and an outer-layer barrier insulating film stacked on the inner-layer insulating film;
the inner-layer barrier insulating film is an oxidation preventing layer which suppresses oxidation of the surface of the copper-containing wiring; and
the barrier insulating film is formed with the organic silica containing the unsaturated hydrocarbon and the amorphous carbon.

4. The semiconductor device as claimed in claim 3, wherein the inner-layer barrier insulating film is a layer which contains no oxygen.

5. The semiconductor device as claimed in claim 3, wherein the amorphous carbon contained in the organic silica structure has both a Sp2 structure and a Sp3 structure.

6. The semiconductor device as claimed in claim 3, wherein the inner-layer barrier insulating film is SiN, SiCN, or SiC.

7. The semiconductor device as claimed in claim 3, wherein the inner-layer barrier insulating film is less than 5 nm in film thickness.

8. The semiconductor device as claimed in claim 1, wherein the copper-containing wiring contains copper as a main component, and has a modified layer or a metal cap layer containing a large amount of impurity elements on its surface.

9. The semiconductor device as claimed in claim 8, wherein the modified layer contains at least one kind selected from silicon (Si), nitrogen (N), titanium (Ti), zirconium (Zr), hafnium (Hf), chrome (Cr), cobalt (Co), tungsten (W), aluminum (Al), tin (Sn), manganese (Mn), magnesium (Mg), and silver (Ag).

10. The semiconductor device as claimed in claim 8, wherein the modified layer is CuSiN, CuSi, or CuN.

11. The semiconductor device as claimed in claim 8, wherein the metal cap layer is COWP, COWB, CoSnP, CoSnB, NiB, or NiMoB.

12. A manufacturing method of a semiconductor device having a copper-containing wiring, comprising:
covering the copper-containing wiring by a barrier insulating film of an organic silica structure which contains unsaturated hydrocarbon and amorphous carbon.

13. The semiconductor device manufacturing method as claimed in claim 12, wherein a surface of the copper-containing wiring is directly covered by the barrier insulating film.

14. The semiconductor device manufacturing method as claimed in claim 12, comprising:
covering a surface of the copper-containing wiring by an inner-layer barrier insulating film which suppresses oxidation of the surface; and
then covering the inner-barrier insulating film by an outer-layer barrier insulating film that has the organic silica structure containing the unsaturated hydrocarbon and the amorphous carbon.

15. The semiconductor device manufacturing method as claimed in claim 12, comprising:
forming a groove, a hole, or a composite opening part configured with the groove and the hole on the insulating film on a substrate where a semiconductor element is formed;
forming a copper-containing metal film by having the film embedded in the groove, the hole, or the composite opening part;
removing and flattening extra copper-containing metal film by polishing to form the copper-containing wiring; and
covering the copper-containing wiring by the barrier insulating film of the organic silica structure which contains the unsaturated hydrocarbon and the amorphous carbon.

16. The semiconductor device manufacturing method as claimed in claim 15, wherein a surface of the copper-containing wiring is directly covered by the barrier insulating film.

17. The semiconductor device manufacturing method as claimed in claim 15, comprising:
covering a surface of the copper-containing wiring by an inner-layer barrier insulating film which suppresses oxidation of the surface; and
then covering the inner-barrier insulating film by an outer-layer barrier insulating film that has the organic silica structure containing the unsaturated hydrocarbon and the amorphous carbon.

18. The semiconductor device manufacturing method as claimed in claim 15, comprising:
forming the barrier metal for preventing diffusion of copper on an inner wall of the groove, the hole, or the composite opening part; and
forming the copper-containing metal film on the barrier metal film.

19. The semiconductor device manufacturing method as claimed in claim 12, wherein an organic silica film is formed by plasma reaction by using a compound having at least one unsaturated hydrocarbon in a side chain of a straight-chain organic silica structure.

20. The semiconductor device manufacturing method as claimed in claim 12, wherein an organic silica film is formed by using a raw material that has a structure shown in following Expression 1.

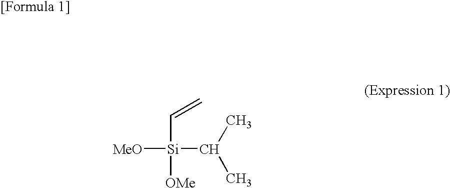

21. The semiconductor device manufacturing method as claimed in claim 13, comprising: forming at least two kinds selected from an inter-via insulating film, an inter-trench film, and a hard mask, after forming the barrier insulating film.

22. The semiconductor device manufacturing method as claimed in claim 21, wherein the barrier insulating film, the inter-via insulating film, the inter-trench film, and the hard mask are formed are formed by a plasma polymerization technique.

23. The semiconductor device manufacturing method as claimed in claim 22, wherein at least one kind selected from raw materials having a straight-chain organic silica structure and raw materials having a cyclic organic silica structure is used as a raw material of the plasma polymerization.

24. The semiconductor device manufacturing method as claimed in claim 23, wherein, as the raw material having the cyclic organic silica structure, a compound having a structure shown in following Expression 2 where R1 and R2 is an unsaturated carbon compound or a saturated carbon compound is used.

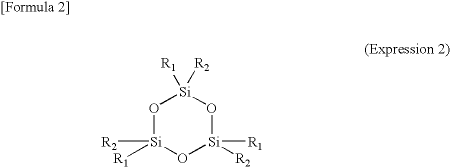

25. The semiconductor device manufacturing method as claimed in claim 23, wherein, as a raw material having the cyclic organic silica structure, a compound that has a structure shown in following Expression 3 is used.

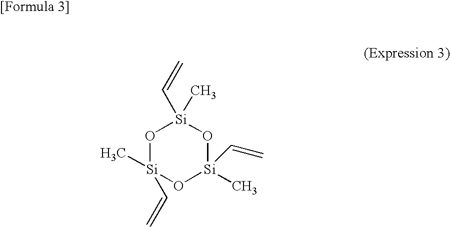

26. The semiconductor device manufacturing method as claimed in claim 23, wherein, as the raw material having the cyclic organic silica structure, a compound having a structure shown in following Expression 4 where R5 is an unsaturated carbon compound, R6, R7, R8 are saturated carbon compounds, R5 is a vinyl radical or an aryl radical, and R6, R7, R8 are a methyl radical, an ethyl radical, a propyl radical, an isopropyl radical, or a butyl radical is used.

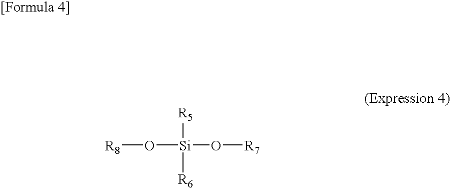

27. The semiconductor device manufacturing method as claimed in claim 23, wherein, as a raw material having the straight-chain organic silica structure, a compound that has a structure shown in following Expression 5 is used.

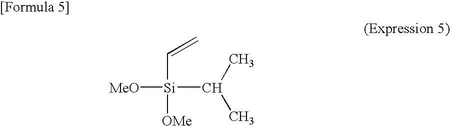

28. The semiconductor device manufacturing method as claimed in claim 14, wherein the inner-layer barrier insulating film of SiN, SiCN, or SiC is formed by a plasma CVD method or by irradiation of composite gas cluster ions containing at least one kind selected from Si, N, and C.

29. The semiconductor device manufacturing method as claimed in claim 28, wherein a gas component containing SiH₄ and a component of at least one kind selected from NH₃, N₂, CH₃, C₂H₂, or C₂H₄ is used as a raw material gas of the composite gas cluster ions.

30. The semiconductor device manufacturing method as claimed in claim 14, wherein the inner-layer barrier insulating film is formed in less than 5 nm in film thickness.

31. The semiconductor device manufacturing method as claimed in claim 12, comprising: forming a modified layer or a metal cap layer having an oxidation resistant property on a surface of the copper-containing wiring.

32. The semiconductor device manufacturing method as claimed in claim 31, wherein the modified layer or the metal cap layer is formed by gas processing by using SiH₄, plasma processing by using NH₃, plasma processing by using SiH₄ and NH₃, or a composite gas cluster ion irradiation by using SiH₄ and at least one kind selected from NH₃, N₂, CH₃, C₂H₂, and C₂H₄.

33. The semiconductor device manufacturing method as claimed in claim 29, wherein the modified layer on the surface of the copper and the barrier insulating film are formed continuously in a same chamber.

34. The semiconductor device manufacturing method as claimed in claim 31, wherein the metal cap layer of CoWP, COWB, CoSnP, CoSnB, NiB, or NiMoB is formed by an electroless plating method.
